(19) United States
(12) Patent Application Publication
(10) Pub. No.: US 2024/0213267 A1
(43) Pub. Date: Jun. 27, 2024

(54) DISPLAY DEVICE

(71) Applicant: LG Display Co., Ltd., Seoul (KR)

(72) Inventors: Yongmin JEONG, Seoul (KR); KiSeob SHIN, Goyang-si (KR); DongHo CHOI, Seoul (KR)

(21) Appl. No.: 18/466,754

(22) Filed: Sep. 13, 2023

(30) Foreign Application Priority Data
Dec. 26, 2022 (KR) 10-2022-0184716

(51) Int. Cl. H01L 27/12; H01L 25/16

(52) U.S. Cl. CPC H01L 27/124; H01L 25/167

(57) ABSTRACT

According to an aspect of the present disclosure, a display device includes a lower substrate which includes an active area and a non-active area and is stretchable; a pattern layer which is disposed on the active area of the lower substrate and includes a plurality of first plate patterns and a plurality of first line patterns; a plurality of pixels which is disposed on each of the plurality of first plate patterns; a plurality of connection lines which is disposed on the plurality of first line patterns and configured to connect the pixels; and a plurality of power connection lines configured to supply a power voltage to the pixels, and the power connection lines are disposed between the pixels on the active area.

### CROSS-REFERENCE TO RELATED APPLICATIONS

This application claims the priority of Korean Patent Application No. 10-2022-0184716 filed on Dec. 26, 2022, in the Korean Intellectual Property Office, the disclosure of which is incorporated herein by reference.

### BACKGROUND

### Technical Field

The present disclosure relates to a display device, and more particularly to a stretchable display device which can be stretched.

### Description of the Related Art

As display devices which are used for a monitor of a computer, a television, or a cellular phone, there are an organic light emitting display (OLED) device which is a self-emitting device and a liquid crystal display (LCD) device which requires a separate light source.

An applicable range of the display device is diversified to personal digital assistants as well as monitors of computers and televisions and a display device with a large display area and a reduced volume and weight is being studied.

Recently, a display device which is manufactured by forming a display unit and a wiring line on a flexible substrate such as plastic which is a flexible material so as to be stretchable in a specific direction and changed in various forms is getting attention as a next generation display device.

### BRIEF SUMMARY

The present disclosure provides a display device which reduces a bezel area.

The present disclosure provides a display device which reduces a deviation of a power voltage due to an internal resistance of a wiring line.

The present disclosure provides a display device with a high resolution and a large area.

The present disclosure provides a display device which improves a luminance uniformity.

Technical features and characteristics of the present disclosure are not limited to those mentioned above, and other technical features and benefits, which are not mentioned above, can be clearly understood by those skilled in the art from the following descriptions.

According to an aspect of the present disclosure, a display device includes a lower substrate which includes an active area and a non-active area and is stretchable; a pattern layer which is disposed on the active area of the lower substrate and includes a plurality of first plate patterns and a plurality of first line patterns; a plurality of pixels which is disposed on each of the plurality of first plate patterns; a plurality of connection lines which is disposed on the plurality of first line patterns and configured to connect the pixels; and a plurality of power connection lines configured to supply a power voltage to the pixels, and the power connection lines are disposed between the pixels on the active area.

Other detailed matters of the example embodiments are included in the detailed description and the drawings.

According to the example embodiments of the present disclosure, the display device includes power connection lines disposed on an active area as a wiring line for supplying a power voltage (for example, a high potential voltage and a low potential voltage). Therefore, a bezel area corresponding to a non-active area of the display device may be reduced.

According to the example embodiments of the present disclosure, in the display device, power connection lines for supplying a power voltage to pixels are disposed in a mesh pattern as a whole. Accordingly, a deviation of the power voltage due to the internal resistance of the wiring line may be reduced so that the luminance uniformity is improved and a display device with a high luminance and a large size may be implemented.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a plan view illustrating a display device according to example embodiments of the present disclosure;

FIG. 2 is an enlarged view of an example of a part A of FIG. 1;

FIG. 3 is a view for explaining an example of a placement relationship of connection lines included in a display device of FIG. 1;

FIG. 4 is a cross-sectional view illustrating an example taken along the line III-III′ of FIG. 2;

FIG. 5 is a cross-sectional view illustrating an example taken along the line IV-IV′ of FIG. 2;

FIG. 6 is a cross-sectional view illustrating an example taken along the line V-V′ of FIG. 2;

FIG. 7 is a view illustrating an example of a placement relationship between a pixel and connection lines included in a display device of FIG. 1;

FIG. 8 is a cross-sectional view illustrating an example taken along the line I-I′ of FIG. 7;

FIG. 9 is a cross-sectional view illustrating an example taken along the line II-II′ of FIG. 7;

FIGS. 10A and 10B are views for explaining a deviation of a power voltage due to an internal resistance of a display device according to Comparative Example of the present disclosure;

FIGS. 11A and 11B are views for explaining a deviation of a power voltage due to an internal resistance of a display device according to example embodiments of the present disclosure;

FIG. 12 is a view illustrating another example of a placement relationship between a pixel and connection lines included in a display device of FIG. 1; and

FIG. 13 is a view illustrating still another example of a placement relationship between a pixel and connection lines included in a display device of FIG. 1.

### DETAILED DESCRIPTION

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to example embodiments of the present disclosure will be described in detail with reference to accompanying drawings.

A display device according to an example embodiment of the present disclosure is a display device which is capable of displaying images even in a bent or extended state and is also referred to as a stretchable display device, a flexible display device and an extendable display device. As compared with the general display devices of the related art, the display device has not only a high flexibility, but also stretchability. Therefore, the user may bend or extend a display device and a shape of a display device may be freely changed in accordance with manipulation of a user. For example, when the user pulls the display device by holding ends of the display device, the display device may be extended to the pulling direction of the user. Alternatively, when the user disposes the display device on an outer surface which is not flat, the display device may be disposed to be bent in accordance with the shape of the outer surface of the wall. Further, when a force applied by the user is removed, the display device may return to its original shape.

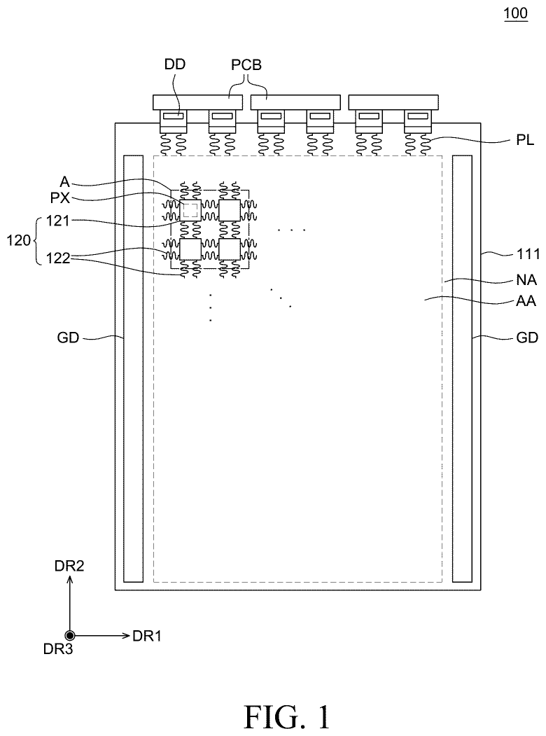

FIG. 1 is a plan view illustrating a display device according to example embodiments of the present disclosure.

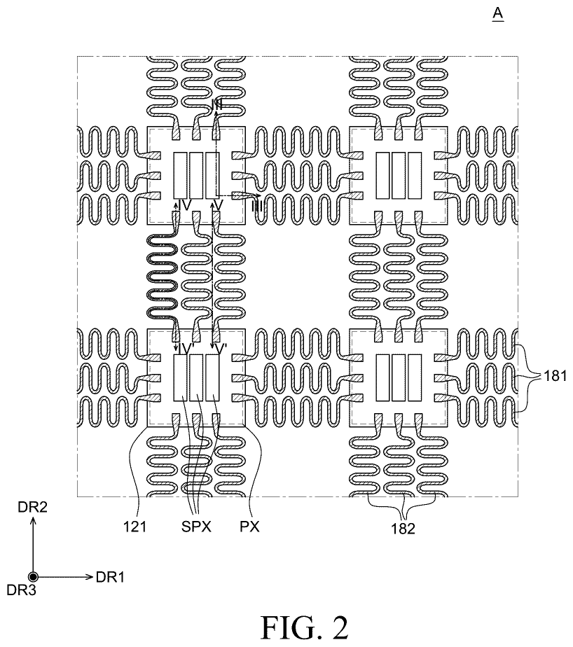

FIG. 2 is an enlarged view of an example of a part A of FIG. 1.

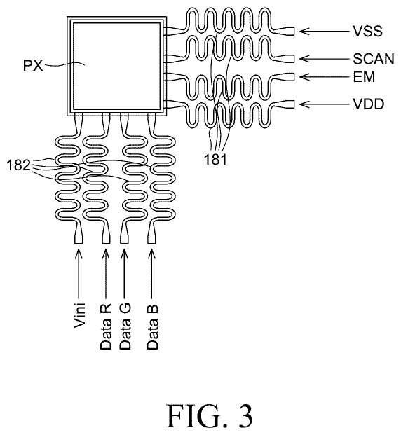

FIG. 3 is a view for explaining an example of a placement relationship of connection lines included in a display device of FIG. 1.

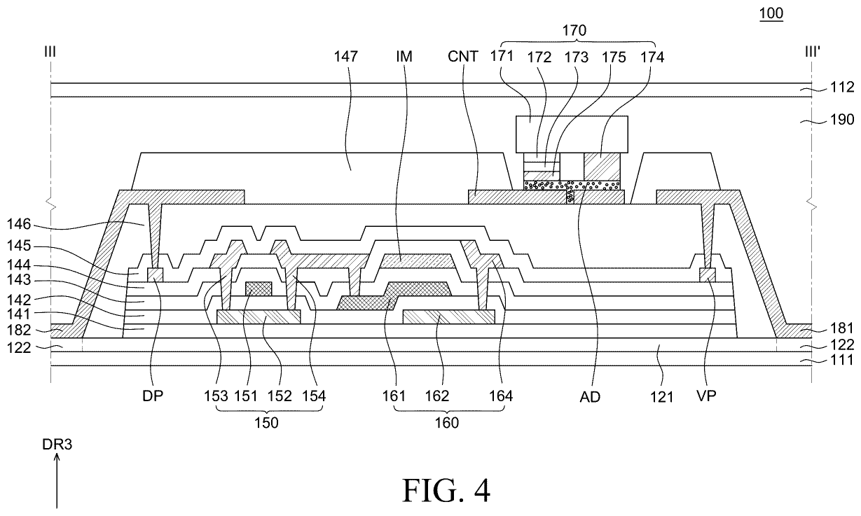

FIG. 4 is a cross-sectional view illustrating an example taken along the line III-III′ of FIG. 2.

Referring to FIGS. 1 to 4, a display device 100 according to an example embodiment of the present disclosure includes a lower substrate 111, a pattern layer 120, a plurality of pixels PX, a gate driver GD, and a data driver DD. In the example embodiment, referring to FIG. 4, the display device 100 may further include a filling layer 190 and an upper substrate 112.

The lower substrate 111 corresponds to a substrate which supports and protects several components of the display device 100. The upper substrate 112 corresponds to a substrate which covers and protects several components of the display device 100. For example, the lower substrate 111 is a substrate which supports a pattern layer 120 on which the pixel PX and the gate driver GD are formed and the upper substrate 112 is a substrate which covers the pixel PX and the gate driver GD.

In one example embodiment, the lower substrate 111 and the upper substrate 112 which are flexible substrates include an insulating material which is bendable or extendable. For example, the lower substrate 111 and the upper substrate 112 may be formed of a silicon rubber such as polydimethylsiloxane (PDMS) or an elastomer such as polyurethane (PU) or polytetrafluoroethylene (PTFE). Accordingly, the lower substrate 111 and the upper substrate 112 may have flexibility. Depending on the example embodiment, the materials of the lower substrate 111 and the upper substrate 112 may be the same, but the example embodiment of the present disclosure is not limited thereto and may vary.

The lower substrate 111 and the upper substrate 112 are flexible substrates so as to be reversibly expandable and contractible. Accordingly, the lower substrate 111 may be referred to as a lower stretchable substrate, a lower stretching substrate, a lower extending substrate, a lower ductile substrate, a lower flexible substrate, a first stretchable substrate, a first stretching substrate, a first extending substrate, a first ductile substrate, or a first flexible substrate. The upper substrate 112 may be referred to as an upper stretchable substrate, an upper stretching substrate, an upper extending substrate, an upper ductile substrate, an upper flexible substrate, a second stretchable substrate, a second stretching substrate, a second extending substrate, a second ductile substrate, or a second flexible substrate. According to the example embodiment, moduli of elasticity of the lower substrate 111 and the upper substrate 112 may be several MPa to several hundreds of MPa. According to the example embodiment, a ductile breaking rate of each of the lower substrate 111 and the upper substrate 112 may be 100% or higher. Here, the ductile breaking rate refers to a stretching rate at a timing when an object to be stretched is broken or cracked. According to the example embodiment, a thickness of the lower substrate may be 10 um to 1 mm, but the example embodiment of the present disclosure is not limited thereto.

The lower substrate 111 may include an active area AA and a non-active area NA which encloses the active area AA. However, the active area AA and the non-active area NA are not mentioned to be limited to the lower substrate 111, but mentioned for the entire display device 100.

The active area AA may be provided as various shapes. For example, the active area AA may be provided as a rectangular planar shape having two pairs of parallel sides and in this case, the display device 100 is also provided to have a rectangular planar shape. However, this is just illustrative so that the example embodiment of the present disclosure is not limited thereto. When the active area AA is provided as a rectangular planar shape, any one pair of sides of two pairs of sides, may be longer than the other pair of sides. In the meantime, for the convenience of description, in FIG. 1, it is illustrated that the active area AA has a rectangular shape having one pair of longer sides and one pair of shorter sides. An extending direction of one pair of longer sides is a second direction DR2 and an extending direction of one pair of shorter sides is a first direction DR1. According to the example embodiment, the active area AA provided as a rectangular planar shape may have a rounded corner in which one longer side and one shorter side are in contact with each other. However, the example embodiment is not limited thereto so that the active area AA may have a square shape, a polygonal shape, or a circular shape.

The active area AA is an area in which images are displayed in the display device 100. A plurality of pixels PX may be disposed on the active area AA. Each pixel PX may include a display element and various driving elements for driving the display element. Various driving elements may refer to at least one thin film transistor (TFT) and a capacitor, but are not limited thereto. The plurality of pixels PX may be connected to various wiring lines, respectively. For example, each of the plurality of pixels PX may be connected to various wiring lines, such as a gate line (for example, a scan signal line or an emission signal line), a data line, a power voltage line (for example, a high potential voltage line and a low potential voltage line), and an initialization voltage line.

The display device 100 displays an image through a display surface, that is, an active area AA. The active area AA may be parallel to a surface having a first directional axis corresponding to the first direction DR1 and a second directional axis corresponding to the second direction DR2. A normal direction of the active area AA, that is, the thickness direction of the display device 100 is referred to as a third direction DR3.

Front surfaces (or top surfaces) and rear surfaces (or bottom surfaces) of components, layers, or units to be described below may be divided by the third direction DR3. However, the first to third directions DR1, DR2, and DR3 are just illustrative and the first to third directions DR1, DR2, and DR3 are relative concepts to be converted to the other directions.

The non-active area NA is an area where no image is displayed. The non-active area NA is disposed to be adjacent to the active area AA. For example, the non-active area NA is an area which encloses the active area AA. However, it is not limited thereto so that the non-active area NA corresponds to an area excluding the active area AA from the lower substrate 111 and may be modified and separated in various forms. Components for driving a plurality of pixels PX disposed in the active area AA may be disposed on the non-active area NA. For example, the gate driver GD may be disposed on the non-active area NA. Further, a plurality of pads which is connected to the data driver DD may be disposed on the non-active area NA and each pad may be connected to the plurality of pixels PX of the active area AA through pad connection lines PL disposed on the non-active area NA.

A pattern layer 120 may be disposed on the lower substrate 111.

In one example embodiment, the pattern layer 120 includes a plurality of first plate patterns 121 disposed on the active area AA. The first plate patterns 121 may be disposed on the active area AA of the lower substrate 111. The plurality of pixels PX is formed on the first plate patterns 121.

In one example embodiment, the pattern layer 120 includes a plurality of first line patterns 122 disposed on the active area AA. The first line patterns 122 are patterns which are disposed on the active area AA and connect the first plate patterns 121 which are adjacent to each other and are referred to as first connection patterns. That is, at least one first line pattern 122 is disposed between the first plate patterns 121.

In one example embodiment, as illustrated in FIG. 1, each of the first line patterns 122 has a wavy shape. For example, the first line patterns 122 may have a sinusoidal shape. However, it is just illustrative, so that the shape of the first line pattern 122 is not limited thereto. For example, each of the first line patterns 122 may have a zigzag shape. As another example, each of the first line patterns 122 may have various shapes, such as a plurality of rhombic substrates being connected and extending at vertices. As described above, the number and the shape of the plurality of first line patterns 122 illustrated in FIG. 1 are illustrative and the number and the shape of the plurality of first line patterns 122 may vary depending on the design.

In one example embodiment, the first plate pattern 121 and the first line pattern 122 may be rigid patterns. For example, the first plate pattern 121 and the first line pattern 122 may be more rigid than the lower substrate 111 and the upper substrate 112. Accordingly, moduli of elasticity of the first plate pattern 121 and the first line pattern 122 may be higher than the modulus of elasticity of the lower substrate 111. The modulus of elasticity is a parameter representing a rate of deformation against the stress applied to the substrate and the higher the modulus of elasticity, the higher the hardness. Therefore, the first plate pattern 121 and the first line pattern 122 may be referred to as a first rigid pattern and a second rigid pattern. For example, moduli of elasticity of the first plate pattern 121 and the first line pattern 122 may be 1000 times higher than the modulus of elasticity of the lower substrate 111 and the upper substrate 112, but it is illustrative and the example embodiment of the present disclosure is not limited thereto.

In the example embodiment, the first plate pattern 121 and the first line pattern 122 may include a plastic material having a lower flexibility than the lower substrate 111 and the upper substrate 112. For example, the first plate pattern 121 and the first line pattern 122 may include at least one of polyimide (PI), polyacrylate, and polyacetate.

According to the example embodiment, the first plate pattern 121 and the first line pattern 122 may be formed of the same material, but are not limited thereto and may be formed of different materials. When the first plate pattern 121 and the first line pattern 122 are formed of the same material, the first plate pattern 121 and the first line pattern 122 may be integrally formed.

According to the example embodiment, the lower substrate 111 includes a first lower pattern and a second lower pattern. The first lower pattern may be an area of the lower substrate 111 overlapping the first plate patterns 121 and the second lower pattern may be an area which does not overlap the first plate patterns 121.

Further, the upper substrate 112 includes a first upper patterns and a second upper pattern. The first upper pattern may be an area of the upper substrate 112 overlapping the first plate patterns 121 and the second upper pattern may be an area which does not overlap the first plate patterns 121.

At this time, moduli of elasticity of the first lower pattern and the first upper pattern may be higher than moduli of elasticity of the second lower pattern and the second upper pattern. For example, the first lower pattern and the first upper pattern are formed of the same material as the first plate pattern 121 and the second lower pattern and the second upper pattern may be formed of a material having a modulus of elasticity lower than the first plate pattern 121.

For example, the first lower pattern and the first upper pattern may be formed of polyimide (PI), polyacrylate, or polyacetate. Further, the second lower pattern and the second upper pattern may be formed of silicon rubber such as polydimethylsiloxane (PDMS) or elastomer such as polyurethane (PU) or polytetrafluoroethylene.

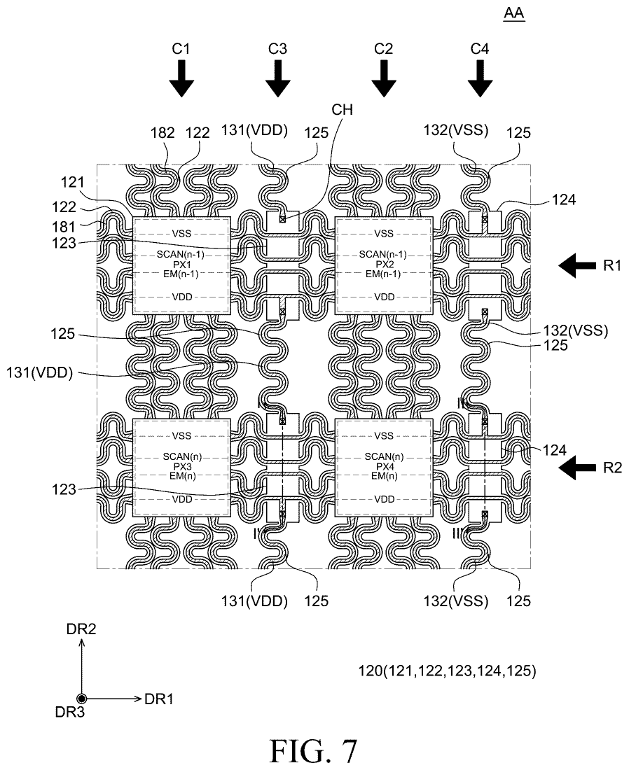

In one example embodiment, as a wiring line for supplying a power voltage (for example, a high potential voltage and a low potential voltage), power connection lines 131 and 132 (see FIG. 7) may be disposed on the active area AA. That is, in the case of the display device 100 according to the example embodiments of the present disclosure, the wiring lines (power connection lines) for supplying a power voltage are not disposed on the non-active area NA (for example, on both sides of the active area AA), but are disposed on the active area AA. By doing this, a bezel area is reduced. Further, according to the example embodiment, the power connection lines 131 and 132 (see FIG. 7) are disposed on the active area AA in the mesh pattern so that the deviation of the power voltage on the active area AA for the internal resistance of the wiring line is reduced. Therefore, the luminance uniformity is improved and the display device with a high resolution and a large size may be implemented.

As described above, in order to dispose the power connection lines 131 and 132 (see FIG. 7) for supplying a power voltage (for example, a high potential voltage and a low potential voltage) on the active area AA, even though it is not illustrated in FIG. 1, the pattern layer 120 further includes second and third plate patterns 123 and 124 (see FIG. 7) disposed on the active area AA and a second line pattern 125 (see FIG. 7). The power connection lines 131 and 132 (see FIG. 7) for supplying power voltages (for example, a high potential voltage and a low potential voltage) may be disposed on the second and third plate patterns 123 and 124 (see FIG. 7) and the second line pattern 125 (see FIG. 7). This will be described in more detail with reference to FIGS. 7 to 9.

The gate driver GD supplies a gate signal to the plurality of pixels PX disposed in the active area AA. For example, the gate driver GD includes a plurality of stages and each stage included in the gate driver GD is electrically connected to each other by means of a plurality of gate connection lines. Accordingly, a gate signal output from any one of stages may be transmitted to the other stage. Each stage may sequentially supply the gate signal to the plurality of pixels PX connected to each stage.

In one example embodiment, the gate driver GD may be disposed on the non-active area NA. For example, the gate driver GD may be mounted on the non-active area NA of the lower substrate 111 in a gate in panel (GIP) manner. Therefore, various circuit configurations which configure the gate driver GD, such as various transistors, capacitors, or wiring lines, may be disposed on the non-active area NA.

In the meantime, even though in FIG. 1, it is illustrated that the gate driver GD is disposed on both sides of the active area AA in the non-active area NA, this is illustrative so that the example embodiment of the present disclosure is not limited thereto. For example, the gate driver GD may be disposed only in one side of the active area AA in the non-active area NA.

The printed circuit board PCB transmits signals and voltages for driving the display element from the control unit to the display element. Therefore, the printed circuit board PCB may also be referred to as a driving substrate. A control unit, such as an IC chip or a circuit unit, may be mounted on the printed circuit board PCB. Further, on the printed circuit board PCB, a memory or a processor may also be mounted. The printed circuit board PCB provided in the display device 100 may include a stretching area and a non-stretching area to ensure stretchability. In the non-stretching area, an IC chip, a circuit unit, a memory, and a processor are mounted and in the stretching area, wiring lines which are electrically connected to the IC chip, the circuit unit, the memory, and the processor may be disposed.

The data driver DD supplies a data signal to the plurality of pixels PX disposed in the active area AA. The data driver DD is configured as an IC chip so that it is also referred to as a data integrated circuit D-IC. The data driver DD may be mounted in the non-stretching area of the printed circuit board PCB. That is, the data driver DD may be mounted on the printed circuit board PCB in the form of a chip on board (COB). Even though in FIG. 1, it is illustrated that the data driver DD is mounted in a chip on film (COF) manner, it is not limited thereto and the data driver DD may be mounted by a chip on board (COB), a chip on glass (COG), or a tape carrier package (TCP) manner.

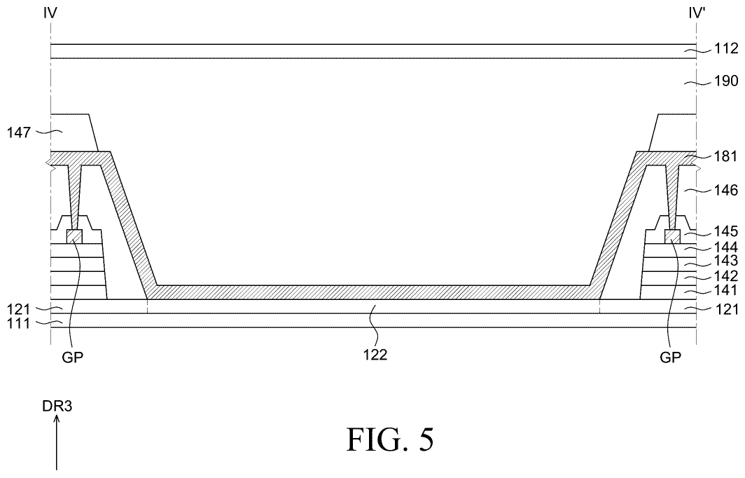

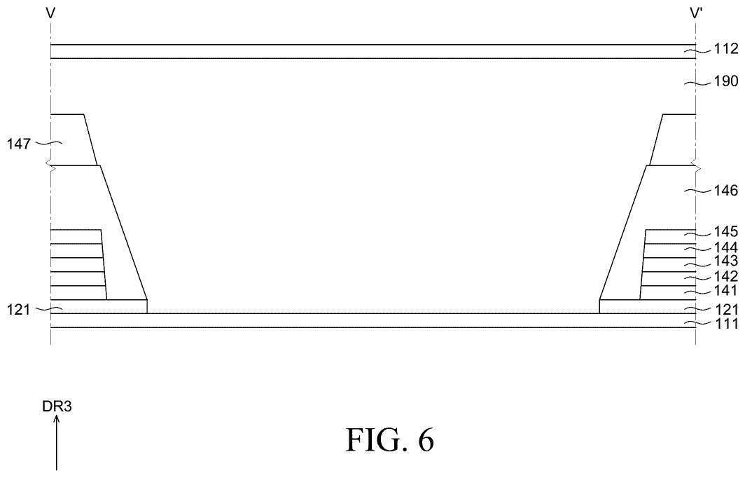

Hereinafter, the active area AA of the display device 100 according to the example embodiment of the present disclosure will be described in more detail with reference to FIGS. 5 and 6 together.

FIG. 5 is a cross-sectional view illustrating an example taken along the line IV-IV′ of FIG. 2.

FIG. 6 is a cross-sectional view illustrating an example taken along the line V-V′ of FIG. 2.

For the convenience of description, the description will be made with reference to FIGS. 1 to 4 together.

Referring to FIGS. 1 and 2, the plurality of first plate patterns 121 is disposed on the lower substrate 111 in the active area AA. The first plate patterns 121 are spaced apart from each other to be disposed on the lower substrate 111. For example, as illustrated in FIGS. 1 and 2, the first plate patterns 121 may be disposed on the lower substrate 111 in a matrix, but this is just illustrative, but the example embodiment of the present disclosure is not limited thereto.

Referring to FIGS. 2 and 4, a pixel PX including the plurality of sub pixels SPX is disposed on the first plate pattern 121. Each of the sub pixels SPX may include an LED 170 which is a display element and a driving transistor 160 and a switching transistor 150 which drive the LED 170. However, in the sub pixel SPX, the display element is not limited to an LED, and may also be changed to an organic light emitting diode. For example, the sub pixels SPX may include a red sub pixel, a green sub pixel, and a blue sub pixel, but is not limited thereto and colors of the sub pixels SPX may be modified to various colors as needed.

The sub pixels SPX may be connected to a plurality of connection lines 181 and 182. For example, the sub pixels SPX is electrically connected to the first connection line 181 extending in the first direction DR1 and is electrically connected to the second connection line 182 extending in the second direction DR2.

In one example embodiment, connection lines 181 and 182 connected to the sub pixels SPX may include various wiring lines, such as a gate line (for example, a scan signal line or an emission signal line), a data line, a power voltage line (for example, a high potential voltage line or a low potential voltage line), and an initialization voltage line.

For example, referring to FIG. 3, in the display device 100 according to the example embodiment of the present disclosure, four first connection lines 181 which are connected to one pixel PX are necessary and four second connection lines 182 which are connected to one pixel PX are necessary.

Specifically, four first connection lines 181 may be a scan signal line which transmits a scan signal SCAN, an emission signal line which transmits an emission signal EM, a low potential voltage line which transmits the low potential voltage VSS, and a high potential voltage line which transmits the high potential voltage VDD. Further, four second connection lines 182 may be an initialization voltage line which transmits an initialization voltage Vini, a red data line which transmits a red data signal Data_R, a green data line which transmits a green data signal Data_G, and a blue data line which transmits a blue data signal Data_B.

Hereinafter, a cross-sectional structure of the active area AA will be described in more detail with reference to FIGS. 4 to 6. In the meantime, for the convenience of description, in FIGS. 4 to 6, only cross-sectional structures of the pixel PX, the first plate pattern 121, the first line pattern 122, and connection lines 181 and 182, among the cross-sectional structures of the active area, are illustrated. A cross-sectional structure of the second and third plate patterns 123 and 124 (see FIG. 7) and the second line pattern 125 (see FIG. 7) disposed on the active area AA which has been described with reference to FIG. 1 and the power connection lines 131 and 132 (see FIG. 7) disposed thereon will be described in more detail with reference to FIGS. 7 to 9.

Referring to FIGS. 1 to 4, an inorganic insulating layer may be disposed on the plurality of first plate patterns 121. For example, the inorganic insulating layer may include a buffer layer 141, a gate insulating layer 142, a first interlayer insulating layer 143, a second interlayer insulating layer 144, and a passivation layer 145. However, the example embodiment of the present disclosure is not limited thereto and various inorganic insulating layers are additionally disposed on the first plate patterns 121. At least one of the buffer layer 141, the gate insulating layer 142, the first interlayer insulating layer 143, the second interlayer insulating layer 144, and the passivation layer 145 which are inorganic insulating layers may be omitted.

To be more specific, the buffer layer 141 is disposed on the first plate patterns 121. The buffer layer 141 is formed on the plurality of first plate patterns 121 to protect various components of the display device 100 from permeation of moisture (H₂O) and oxygen (O₂) from the outside of the lower substrate 111 and the plurality of first plate patterns 121. The buffer layer 141 may be configured by an insulating material. For example, the buffer layer 141 may be configured by a single layer or a double layer formed of at least one of silicon nitride (SiNx), silicon oxide (SiOx), and silicon oxynitride (SiON). However, the buffer layer 141 may be omitted depending on a structure or a characteristic of the display device 100.

In one example embodiment, the buffer layer 141 may be formed only in an area where the lower substrate 111 overlaps the first plate patterns 121 which has been described with reference to FIG. 1 and the second and third plate patterns 123 and 124 (see FIG. 7). As described above, the buffer layer 141 may be formed of an inorganic material so that the buffer layer 141 may be easily cracked or damaged during a process of stretching the display device 100. Therefore, the buffer layer 141 is not formed in an area between the first plate patterns 121 and the second and third plate patterns 123 and 124 (see FIG. 7). Instead, the buffer layer 141 is patterned to have a shape of the first plate patterns 121 and the second and third plate patterns 123 and 124 (see FIG. 7) to be formed only above the first plate patterns 121 and the second and third plate patterns 123 and 124 (see FIG. 7). Therefore, in the display device 100 according to the example embodiment of the present disclosure, the buffer layer 141 is formed only in an area overlapping the first plate patterns 121 and the second and third plate patterns 123 and 124 (see FIG. 7) which are rigid patterns. Therefore, even though the display device 100 is bent or extended to be deformed, the damage of various components of the display device 100 may be suppressed.

A switching transistor 150 including a gate electrode 151, an active layer 152, a source electrode 153, and a drain electrode 154 and a driving transistor 160 including a gate electrode 161, an active layer 162, a source electrode and a drain electrode 164 are disposed (or formed) on the buffer layer 141.

First, the active layer 152 of the switching transistor 150 and the active layer 162 of the driving transistor 160 are disposed on the buffer layer 141. For example, the active layer 152 of the switching transistor 150 and the active layer 162 of the driving transistor 160 may be formed of oxide semiconductors. Alternatively, the active layer 152 of the switching transistor 150 and the active layer 162 of the driving transistor 160 may be formed of amorphous silicon (a-Si), polycrystalline silicon (poly-Si), or an organic semiconductor.

The gate insulating layer 142 is disposed on the active layer 152 of the switching transistor 150 and the active layer 162 of the driving transistor 160. The gate insulating layer 142 electrically insulates the gate electrode 151 of the switching transistor 150 from the active layer 152 of the switching transistor 150 and electrically insulates the gate electrode 161 of the driving transistor 160 from the active layer 162 of the driving transistor 160. The gate insulating layer 142 may include an insulating material. For example, the gate insulating layer 142 may be configured by a single layer of silicon nitride (SiNx) or silicon oxide (SiOx) which is an inorganic material or a multiple layer of silicon nitride (SiNx) or silicon oxide (SiOx), but it is not limited thereto.

The gate electrode 151 of the switching transistor 150 and the gate electrode 161 of the driving transistor 160 are disposed on the gate insulating layer 142. The gate electrode 151 of the switching transistor 150 and the gate electrode 161 of the driving transistor 160 are disposed on the gate insulating layer 142 to be spaced apart from each other. The gate electrode 151 of the switching transistor 150 overlaps the active layer 152 of the switching transistor 150 and the gate electrode 161 of the driving transistor 160 overlaps the active layer 162 of the driving transistor 160.

The gate electrode 151 of the switching transistor 150 and the gate electrode 161 of the driving transistor 160 may be any one of various metal materials such as molybdenum (Mo), aluminum (Al), chrome (Cr), gold (Au), titanium (Ti), nickel (Ni), neodymium (Nd), and copper (Cu) or an alloy of two or more of them, or a multiple layer thereof, but it is not limited thereto.

The first interlayer insulting layer 143 is disposed on the gate electrode 151 of the switching transistor 150 and the gate electrode 161 of the driving transistor 160. The first interlayer insulating layer 143 insulates the gate electrode 161 of the driving transistor 160 from an intermediate metal layer IM. The first interlayer insulating layer 143 may be formed of an inorganic material, similar to the buffer layer 141. For example, the first interlayer insulating layer 143 may be configured by a single layer of silicon nitride (SiNx) or silicon oxide (SiOx) which is an inorganic material or a multiple layer of silicon nitride (SiNx) or silicon oxide (SiOx), but it is not limited thereto.

The intermediate metal layer IM is disposed on the first interlayer insulating layer 143. The intermediate metal layer IM overlaps the gate electrode 161 of the driving transistor 160. Therefore, a capacitor (for example, a storage capacitor) is formed in an overlapping area of the intermediate metal layer IM and the gate electrode 161 of the driving transistor 160. Specifically, the storage capacitor may be formed by the gate electrode 161 of the driving transistor 160, the first interlayer insulating layer 143, and the intermediate metal layer IM. However, the placement area of the intermediate metal layer IM is not limited thereto and the intermediate metal layer IM overlaps the other electrode to form the storage capacitor in various forms.

The intermediate metal layer IM may be any one of various metal materials, for example, any one of molybdenum (Mo), aluminum (Al), chrome (Cr), gold (Au), titanium (Ti), nickel (Ni), neodymium (Nd), and copper (Cu) or an alloy of two or more of them, or a multiple layer thereof, but it is not limited thereto.

The second interlayer insulating layer 144 is disposed on the intermediate metal layer IM. The second interlayer insulating layer 144 insulates the gate electrode 151 of the switching transistor 150 from the source electrode 153 and the drain electrode 154 of the switching transistor 150. The second interlayer insulating layer 144 insulates the intermediate metal layer IM from the source electrode and the drain electrode 164 of the driving transistor 160. The second interlayer insulating layer 144 may be formed of an inorganic material, which is the same as the buffer layer 141. For example, the first interlayer insulating layer 143 may be configured by a single layer of silicon nitride (SiNx) or silicon oxide (SiOx) which is an inorganic material or a multiple layer of silicon nitride (SiNx) or silicon oxide (SiOx), but it is not limited thereto.

The source electrode 153 and the drain electrode 154 of the switching transistor 150 are disposed on the second interlayer insulating layer 144. The source electrode and the drain electrode 164 of the driving transistor 160 are disposed on the second interlayer insulating layer 144. The source electrode 153 and the drain electrode 154 of the switching transistor 150 are disposed on the same layer to be spaced apart from each other. Even though in FIG. 4, the source electrode of the driving transistor 160 is omitted, the source electrode of the driving transistor 160 is also disposed to be spaced apart from the drain electrode 164 on the same layer. In the switching transistor 150, the source electrode 153 and the drain electrode 154 may be in contact with the active layer 152 to be electrically connected to the active layer 152. In the driving transistor 160, the source electrode and the drain electrode 164 may be in contact with the active layer 162 to be electrically connected to the active layer 162. The drain electrode 154 of the switching transistor 150 is in contact with the gate electrode 161 of the driving transistor 160 through a contact hole to be electrically connected to the gate electrode 161 of the driving transistor 160.

The source electrode 153 and the drain electrodes 154 and 164 may include any one of various metal materials such as molybdenum (Mo), aluminum (Al), chrome (Cr), gold (Au), titanium (Ti), nickel (Ni), neodymium (Nd), and copper (Cu) or an alloy of two or more of them, or a multiple layer thereof, but it is not limited thereto.

Further, in this specification, even though it is described that the driving transistor 160 has a coplanar structure, various transistors such as a staggered structure may also be used. Further, in this specification, the transistor may be formed not only to have a top gate structure, but also to have a bottom gate structure.

A gate pad GP and a data pad DP may be disposed on the second interlayer insulating layer 144.

Specifically, referring to FIG. 5, the gate pad GP is a pad which transmits a gate signal to the plurality of sub pixels SPX. The gate pad GP is connected to the first connection line 181 through a contact hole. The gate signal supplied from the first connection line 181 may be transmitted to the gate electrode 151 of the switching transistor 150 from the gate pad GP through a wiring line formed on the first plate pattern 121.

Referring to FIG. 4 again, the data pad DP is a pad which transmits a data signal to the plurality of sub pixels SPX. The data pad DP is connected to the second connection line 182 through a contact hole. The data signal supplied from the second connection line 182 may be transmitted to the source electrode 153 of the switching transistor 150 from the data pad DP through a wiring line formed on the first plate pattern 121.

The voltage pad VP is a pad which transmits a low potential voltage to the sub pixels SPX. The voltage pad VP is connected to the first connection line 181 through a contact hole. The low potential voltage supplied from the first connection line 181 may be transmitted to the n-electrode 174 of the LED 170 from the voltage pad VP through a wiring line formed on the first plate pattern 121.

The gate pad GP and the data pad DP may be formed of the same material as the source electrode 153 and the drain electrodes 154 and 164, but are not limited thereto.

The passivation layer 145 may be formed on the switching transistor 150 and the driving transistor 160. That is, the passivation layer 145 covers the switching transistor 150 and the driving transistor 160 to protect the switching transistor 150 and the driving transistor 160 from the permeation of moisture and oxygen. The passivation layer 145 may be formed of an inorganic material and configured by a single layer or a double layer, but is not limited thereto.

Further, the gate insulating layer 142, the first interlayer insulating layer 143, the second interlayer insulating layer 144, and the passivation layer 145 are patterned to be formed only in an area overlapping the first plate patterns 121 and the second and third plate patterns 123 and 124 (see FIG. 7). The gate insulating layer 142, the first interlayer insulating layer 143, the second interlayer insulting layer 144, and the passivation layer 145 are also formed of the inorganic material, similar to the buffer layer 141. Therefore, the gate insulating layer 142, the first interlayer insulating layer 143, the second interlayer insulating layer 144, and the passivation layer 145 may also be easily cracked to be damaged during the process of stretching the display device 100. Accordingly, the gate insulating layer 142, the first interlayer insulating layer 143, the second interlayer insulating layer 144, and the passivation layer 145 are not formed in an area between the first plate patterns 121 and the second and third plate patterns 123 and 124 (see FIG. 7), but are patterned to have the shape of the first plate patterns 121 and the second and third plate patterns 123 and 124 (see FIG. 7) to be formed only above first plate patterns 121 and the second and third plate patterns 123 and 124 (see FIG. 7).

The planarization layer 146 is formed on the passivation layer 145. The planarization layer 146 planarizes upper portions of the switching transistor 150 and the driving transistor 160. The planarization layer 146 may be configured by a single layer or a plurality of layers and may be formed of an organic material. Therefore, the additional planarization layer 146 may also be referred to as an organic insulating layer. For example, the planarization layer 146 may be formed of an acrylic organic material, but is not limited thereto.

The planarization layer 146 may be disposed so as to cover top surfaces and side surfaces of the buffer layer 141, the gate insulating layer 142, the first interlayer insulating layer 143, the second interlayer insulating layer 144, and the passivation layer 145 on the plurality of first plate patterns 121. The planarization layer 146 encloses the buffer layer 141, the gate insulating layer 142, the first interlayer insulating layer 143, the second interlayer insulating layer 144, and the passivation layer 145 together with the plurality of first plate patterns 121. To be more specific, the planarization layer 146 may be disposed so as to cover a top surface and a side surface of the passivation layer 145, a side surface of the first interlayer insulating layer 143, a side surface of the second interlayer insulating layer 144, a side surface of the gate insulating layer 142, a side surface of the buffer layer 141, and a part of a top surface of the plurality of first plate patterns 121. Accordingly, the planarization layer 146 may supplement a step on side surfaces of the buffer layer 141, the gate insulating layer 142, the first interlayer insulating layer 143, the second interlayer insulating layer 144, and the passivation layer 145. Further, the planarization layer 146 may enhance an adhesive strength of the connection lines 181 and 182 disposed on a side surface of the planarization layer 146.

As illustrated in FIG. 4, an inclination angle of the side surface of the planarization layer 146 may be smaller than an inclination angle formed by side surfaces of the buffer layer 141, the gate insulating layer 142, the first interlayer insulating layer 143, the second interlayer insulating layer 144, and the passivation layer 145. For example, the side surface of the planarization layer 146 may have a slope which is gentler than a slope formed by the side surface of the passivation layer 145, the side surface of the first interlayer insulating layer 143, the side surface of the second interlayer insulating layer 144, the side surface of the gate insulating layer 142, and the side surface of the buffer layer 141. Therefore, the connection lines 181 and 182 which are disposed to be in contact with the side surface of the planarization layer 146 are disposed with a gentle slope so that when the display device 100 is stretched, the stress generated in the connection lines 181 and 182 may be reduced. Further, the side surface of the planarization layer 146 has a relatively gentle slope so that the crack of the connection lines 181 and 182 or separation thereof from the side surface of the planarization layer 146 may be suppressed.

Referring to FIGS. 2 to 5, the connection lines 181 and 182 refer to wiring lines which electrically connect the pads on the first plate patterns 121. The connection lines 181 and 182 are disposed on the first line patterns 122. The connection lines 181 and 182 may extend also onto the first plate patterns 121 to be electrically connected to the gate pad GP and the data pad DP on the first plate patterns 121. In the meantime, the first line pattern 122 is not disposed in an area where the connection lines 181 and 182 are not disposed, among areas between the plurality of first plate patterns 121.

The connection lines 181, 182 include a first connection line 181 and a second connection line 182. The first connection line 181 and the second connection line 182 are disposed between the plurality of first plate patterns 121. Specifically, the first connection line 181 refers to a wiring line extending in a first direction DR1 between the first plate patterns 121, among the connection lines 181 and 182. The second connection line 182 refers to a wiring line extending in a second direction DR2 between the first plate patterns 121, among the connection lines 181 and 182.

The connection lines 181 and 182 may be formed of a metal material such as copper (Cu), aluminum (Al), titanium (Ti), and molybdenum (Mo) or a stacked structure of metal materials such as copper/molybdenum-titanium (Cu/Moti) or titanium/aluminum/titanium (Ti/Al/Ti), but is not limited thereto.

In the case of a display panel of a general display device, various wiring lines such as a plurality of gate lines and a plurality of data lines extend between the plurality of sub pixels as a straight line and the plurality of sub pixels is connected to one signal line. Therefore, in the display panel of the general display device, various wiring lines, such as a gate line, a data line, a power voltage line, and an initialization voltage line, extend from one side to the other side of the display panel of the organic light emitting display device without being disconnected on the substrate.

In contrast, in the display device 100 according to the example embodiments of the present disclosure, various wiring lines, such as a gate line, a data line, a power voltage line (for example, a high potential voltage line and a low potential voltage line), and an initialization voltage line having a straight line shape which are considered to be used for the display panel of the general display device, is disposed only on the first plate patterns 121 and the second and third plate patterns 123 and 124 (see FIG. 7). That is, in the display device 100 according to the example embodiment of the present disclosure, a straight wiring line is disposed only on the first plate patterns 121 and the second and third plate patterns 123 and 124 (see FIG. 7).

In the display device 100 according to the example embodiment of the present disclosure, the pads on two adjacent first plate patterns 121 may be connected by the connection lines 181 and 182. Accordingly, the connection lines 181 and 182 electrically connect the gate pads GP or the data pads DP on two adjacent first plate patterns 121. As described above, the display device 100 according to the example embodiments of the present disclosure may include a plurality of connection lines 181 and 182 so as to electrically connect various wiring lines, such as a gate line, a data line, a power voltage line (for example, a high potential voltage line and a low potential voltage line), and an initialization voltage line between the plurality of first plate patterns 121. For example, the gate line may be disposed on the plurality of first plate patterns 121 disposed to be adjacent to each other in the first direction DR1 and the gate pad GP may be disposed on both ends of the gate line. At this time, each of the gate pads GP on the plurality of first plate patterns 121 adjacent to each other in the first direction DR1 may be connected to each other by the first connection line 181 which serves as a gate line. Therefore, the gate line disposed on the first plate patterns 121 and the first connection line 181 disposed on the first line pattern 122 may serve as one gate line. The above-described gate line may be referred to as a scan signal line or an emission signal line. Further, wiring lines which extend in the first direction DR1, among all various wiring lines which may be included in the display device 100, such as a low potential voltage line and a high potential voltage line, may also be electrically connected by the first connection line 181, as described above.

Referring to FIGS. 2, 3, and 5, the first connection lines 181 may connect the gate pads GP on two first plate patterns 121 which are disposed side by side, among the gate pads GP on the plurality of first plate patterns 121 disposed to be adjacent in the first direction DR1. The first connection line 181 may serve as a gate line (for example, a scan signal or an emission signal line), a high potential voltage line, or a low potential voltage line, but is not limited thereto. The gate pads GP on the plurality of first plate patterns 121 disposed in the first direction DR1 may be connected by the first connection line 181 serving as a gate line and transmit one gate signal.

Further, referring to FIGS. 2, 3, and 4, the second connection line 182 may connect the data pads DP on two first plate patterns 121 which are disposed side by side, among the data pads DP on the plurality of first plate patterns 121 disposed to be adjacent in the second direction DR2. The second connection line 182 may serve as a data line or an initialization voltage line, but is not limited thereto. The internal line on the plurality of first plate patterns 121 disposed in the second direction DR2 may be connected by the second connection lines 182 serving as a data line and transmit one data signal.

As illustrated in FIG. 5, the first connection line 181 is disposed to be in contact with a top surface and a side surface of the planarization layer 146 disposed on the first plate pattern 121. The first connection line 181 may be formed to extend onto the top surface of the first line pattern 122. Further, the second connection line 182 is disposed to be in contact with a top surface and a side surface of the planarization layer 146 disposed on the first plate pattern 121. The second connection line 182 may be formed to extend onto the top surface of the first line pattern 122.

However, as illustrated in FIG. 6, there is no need to dispose a rigid pattern in an area where the first connection line 181 and the second connection line 182 are not disposed. Therefore, the first line pattern 122 which is a rigid pattern is not disposed below the first connection line 181 and the second connection line 182.

In the meantime, referring to FIG. 4, a bank 147 is formed on the connection pad CNT, the connection lines 181 and 182, and the planarization layer 146. The bank 147 divides adjacent sub pixels SPX. The bank 147 is disposed so as to cover at least a part of the connection pad CNT, the connection lines 181 and 182, and the planarization layer 146. The bank 147 may include an insulating material. Further, the bank 147 may include a black material. The bank 147 includes the black material to block wiring lines which may be visible through the active area AA. For example, the bank 147 may be formed of a transparent carbon based mixture and for example, include carbon black. However, it is not limited thereto and the bank 147 may be formed of a transparent insulating material. In the meantime, even though in FIG. 4, it is illustrated that a height of the bank 147 is lower than a height of the LED 170, this is just illustrative, so that the example embodiment of the present disclosure is not limited thereto and the height of the bank 147 may be equal to the height of the LED 170.

Referring to FIG. 4, the LED 170 is disposed on the connection pad CNT and the first connection line 181. The LED 170 may include an n-type layer 171, an active layer 172, a p-type layer 173, an n electrode 174, and a p electrode 175. The LED 170 of the display device 100 according to the example embodiment of the present disclosure has a flip-chip structure in which the n-electrode 174 and the p-electrode 175 are formed on one surface.

The n-type layer 171 may be formed by injecting an n-type impurity into gallium nitride (GaN) having excellent crystallinity. The n-type layer 171 may be disposed on a separate base substrate which is formed of a material which is capable of emitting light.

The active layer 172 may be disposed on the n-type layer 171. The active layer 172 is an emission layer which emits light in the LED 170 and may be formed of a nitride semiconductor, for example, indium gallium nitride (InGaN). The p-type layer 173 may be disposed on the active layer 172. The p-type layer 173 may be formed by injecting a p-type impurity into gallium nitride (GaN).

The LED 170 according to the example embodiment of the present disclosure may be manufactured by sequentially laminating the n-type layer 171, the active layer 172, and the p-type layer 173, and then etching a predetermined part to form the n-electrode 174 and the p-electrode 175. In this case, a predetermined part is a space for separating the n electrode 174 and the p electrode 175 from each other and the predetermined part may be etched to expose a part of the n-type layer 171. In other words, the surfaces of the LED 170 on which the n-electrode 174 and the p-electrode 175 are disposed are not flat surfaces, but have different heights.

As described above, the n-electrode 174 is disposed in the etched area and is formed of a conductive material. Further, the p-electrode 175 is disposed in an area which is not etched and is also formed of a conductive material. For example, the n-electrode 174 is disposed on the n-type layer 171 which is exposed by the etching process and the p-electrode 175 is disposed on the p-type layer 173. The p-electrode 175 may be formed of the same material as the n-electrode 174.

An adhesive layer AD is disposed on top surfaces of the connection pad CNT and the first connection line 181 and between the connection pad CNT and the first connection line 181 so that the LED 170 may be adhered onto the connection pad CNT and the first connection line 181. At this time, the n-electrode 174 is disposed on the first connection line 181 and the p-electrode 175 is disposed on the connection pad CNT.

The adhesive layer AD may be a conductive adhesive layer in which conductive balls are dispersed in an insulating base member. Therefore, when heat or a pressure is applied to the adhesive layer AD, the conductive balls are electrically connected in a portion applied with the heat or pressure to have a conductive property and an area which is not pressurized may have an insulation property. For example, the n-electrode 174 is electrically connected to the first connection line 181 by means of the adhesive layer AD and the p-electrode 175 is electrically connected to the connection pad CNT by means of the adhesive layer AD. After applying the adhesive layer AD onto the top surface of the first connection line 181 and the connection pad CNT by an inkjet method, the LED 170 is transferred onto the adhesive layer AD and is pressurized and heated. By doing this, the connection pad CNT is electrically connected to the p-electrode 175 and the first connection line 181 is electrically connected to the n-electrode 174. However, the remaining part of the adhesive layer AD excluding a part of the adhesive layer AD disposed between the n-electrode 174 and the first connection pad 181 and a part of the adhesive layer AD disposed between the p-electrode 175 and the connection pad CNT has an insulation property. In the meantime, the adhesive layer AD may be divided to be disposed on the connection pad CNT and the first connection line 181, respectively.

The connection pad CNT is electrically connected to the drain electrode 164 of the driving transistor 160 to be applied with a driving voltage from the driving transistor 160 to drive the LED 170. In the meantime, even though in FIG. 4, it is illustrated that the connection pad CNT is not in direct contact with the drain electrode 164 of the driving transistor 160, but is in indirect contact therewith, the present disclosure is not limited thereto. Therefore, the connection pad CNT1 and the drain electrode 164 of the driving transistor 160 may be in direct contact with each other. Further, a low potential driving voltage is applied to the first connection line 181 to drive the LED 170. Therefore, when the display device 100 is turned on, different voltage levels applied to the connection pad CNT and the first pixel connection line 181 are transmitted to the n-electrode 174 and the p-electrode 175 so that the LED 170 emits light.

The upper substrate 112 covers various components disposed below the upper substrate 112. To be more specific, the upper substrate 112 is formed by coating a material which configures the upper substrate 112 on the lower substrate 111 and the first plate pattern 121 and then hardening the material to be in contact with the lower substrate 111, the first plate pattern 121, the second line pattern 122, and the connection lines 181 and 182.

The upper substrate 112 may be formed of the same material as the lower substrate 111. For example, the upper substrate 112 includes a silicon rubber such as polydimethylsiloxane (PDMS) or an elastomer such as polyurethane (PU) or polytetrafluoroethylene (PTFE) and thus has a flexible property. However, the material of the upper substrate 112 is not limited thereto.

Even though not illustrated in FIGS. 4 to 6, a polarization layer may be disposed on the upper substrate 112. The polarization layer may perform a function which polarizes light incident from the outside of the display device 100 to reduce the external light reflection. Further, an optical film other than the polarization layer may be disposed on the upper substrate 112.

According to the example embodiment, the filling layer 190 is disposed on the entire surface of the lower substrate 111 to be filled between the components disposed on the upper substrate 112 and the lower substrate 111. The filling layer 190 may be configured by a curable adhesive. Specifically, the material which configures the filling layer 190 is coated on the entire surface of the lower substrate 111 and then is cured so that the filling layer 190 may be disposed between the upper substrate 112 and the components disposed on the lower substrate 111. For example, the filling layer 190 may be an optically clear adhesive (OCA) and may be configured by an acrylic adhesive, a silicon based adhesive, and an urethane based adhesive.

As described with reference to FIGS. 1 to 6, the display device 100 according to the example embodiments of the present disclosure is stretched with a structure including a lower substrate 111 and an upper substrate 112 which are flexible substrates and first line patterns 122 and connection lines 181 and 182 having a wavy shape.

Further, as described above, in the display device 100 according to the example embodiments of the present disclosure, as a wiring line for supplying a power voltage (for example, a high potential voltage and a low potential voltage), power connection lines 131 and 132 (see FIG. 7) are disposed on the active area AA. Therefore, the bezel area of the display device 100 may be reduced. Further, the power connection lines 131 and 132 (see FIG. 7) are disposed on the active area AA in the mesh pattern so that the deviation of the power voltage on the active area AA due to the internal resistance of the wiring line is reduced. Therefore, in the entire active area AA, the luminance uniformity is improved so that the display device 100 with a high resolution and a large size may be implemented.

Hereinafter, specific configurations for disposing the power connection lines on the active area AA, a placement relationship of configurations, and a cross-sectional structure will be described in more detail with reference to FIGS. 7 to 9.

FIG. 7 is a view illustrating an example of a placement relationship between a pixel and connection lines included in a display device of FIG. 1.

In the meantime, in FIG. 7, for the convenience of description, only four pixels PX1 to PX4, among pixels PX disposed on the active area AA of the display device 100 are illustrated.

Referring to FIGS. 1 to 7, pixels PX1 to PX4 are disposed to be spaced apart from each other. For example, as described with reference to FIGS. 1 to 6, pixels PX1 to PX4 are disposed on the plurality of first plate patterns 121 which is disposed on the lower substrate 111 and is spaced apart from each other as island shapes. For example, in a first row R1, first and second pixels PX1 and PX2 are sequentially disposed along the first direction DR1 to be spaced apart from each other. Further, in a second row R2 adjacent to the first row R1 along the second direction DR2, the third and fourth pixels PX3 and PX4 are sequentially disposed along the first direction DR1 to be spaced apart from each other. As another example, in a first column C1, first and third pixels PX1 and PX3 are sequentially disposed along the second direction DR2 to be spaced apart from each other. Further, in a second column C2 adjacent to the first column C1 along the first direction DR1, the second and fourth pixels PX2 and PX4 are sequentially disposed along the second direction DR2 to be spaced apart from each other.

Here, the rows R1 and R2 refer to pixel rows on the active area AA and the columns C1 and C2 refer to pixel columns on the active area AA. For example, when the first row R1 is a n-1-th (n is an integer of 0 or larger) pixel row, first and second pixels PX1 and PX2 disposed in the first row R1 are supplied with a n-1-th scan signal SCAN(n-1) through a n-1-th scan signal line, among the first connection lines 181. Further, the first and second pixels PX1 and PX2 disposed in the first row R1 are supplied with a n-1-th emission signal EM(n-1) through a n-1-th emission signal line, among the first connection lines 181. Similarly, when the second row R2 is a n-th pixel row, third and fourth pixels PX3 and PX4 disposed in the second row R2 are supplied with a n-th scan signal SCAN(n) through a n-th scan signal line, among the first connection lines 181. Further, the third and fourth pixels PX3 and PX4 disposed in the second row R2 are supplied with a n-th emission signal EM(n) through a n-th emission signal line, among the first connection lines 181.

Further, as described with reference to FIGS. 1 to 6, the pixels PX1 to PX4 disposed on the first plate pattern 121 are electrically connected to the first line pattern 122 and the connection lines 181 and 182 to be supplied with various signals and various voltages. For example, various signals include a scan signal, an emission signal, and a data signal and various voltages include a high potential voltage, a low potential voltage, and an initialization voltage.

For example, the first connection lines 181 may be disposed on the first line patterns 122 which are disposed to extend along the first direction DR1 between the first plate patterns 121 adjacent along the first direction DR1. That is, the first connection lines 181 extend along the first direction DR1 and are disposed between the first plate patterns 121. Here, a scan signal SCAN(n-1) or SCAN(n) is transmitted to the pixels PX1 to PX4 through a first connection line 181 serving as a scan signal line, among the first connection lines 181. Further, an emission signal EM(n-1) or EM(n) is transmitted to the pixels PX1 to PX4 through a first connection line 181 serving as an emission signal line, among the first connection lines 181. Further, a high potential voltage VDD is supplied to the pixels PX1 to PX4 through a first connection line 181 serving as a high potential voltage line, among the first connection lines 181. Further, a low potential voltage VSS is supplied to the pixels PX1 to PX4 through a first connection line 181 serving as a low potential voltage line, among the first connection lines 181.

Further, the second connection lines 182 may be disposed on the first line patterns 122 which are disposed to extend along the second direction DR2 between the first plate patterns 121 adjacent along the second direction DR2. That is, the second connection lines 182 extend along the second direction DR2 and are disposed between the first plate patterns 121. Here, a data signal is transmitted to the pixels PX1 to PX4 through second connection lines 182 serving as data signal lines, among the second connection lines 182. Further, an initialization voltage supplied to the pixels PX1 to PX4 through a second connection line 182 serving as an initialization voltage line, among the second connection lines 182.

In the meantime, as described above, in the case of the display device 100 according to the example embodiments of the present disclosure, as a wiring line for supplying a power voltage (for example, a high potential voltage VDD and a low potential voltage VSS), first and second power connection lines 131 and 132 are disposed on the active area AA.

In order to dispose the first and second power connection lines 131 and 132 on the active area AA, in one example embodiment, a pattern layer 120 included in the display device 100 further includes a plurality of second plate patterns 123, a plurality of third plate patterns 124, and a plurality of second line patterns 125.

The second plate patterns 123 and the third plate patterns 124 may be disposed on the active area AA of the lower substrate 111. On the second plate patterns 123 and the third plate patterns 124, some of the first and second power connection lines 131 and 132 for supplying the power voltage and some of the first connection lines 181 disposed along the first direction DR1 may be disposed.

In one example embodiment, the second plate patterns 123 are disposed as islands shapes which are spaced apart from each other. Similarly, the third plate patterns 124 are disposed as islands shapes which are spaced apart from each other.

Further, each of the second plate patterns 123 and each of the third plate patterns 124 may have a rectangular shape elongated along the second direction DR2 which is the same as the extending direction of the first and second power connection lines 131 and 132. For example, each of the second plate patterns 123 and each of the third plate patterns 124 have a rectangular shape in which long sides are parallel to the second direction DR2 and short sides are parallel to the first direction DR1.

In one example embodiment, each of the second plate patterns 123 may be disposed in an area between the first plate patterns 121 so as not to overlap the first plate patterns 121 in which the pixels PX1 to PX4 are disposed. Similarly, each of the third plate patterns 124 may be disposed in an area between the first plate patterns 121 so as not to overlap the first plate patterns 121 in which the pixels PX1 to PX4 are disposed.

For example, the second plate patterns 123 may be disposed on the third column C3 which is adjacent to the first column C1 along the first direction DR1 and is disposed between the first column C1 and the second column C2. For example, the second plate pattern 123 may be disposed between the first pixel PX1 and the second pixel PX2 or between the third pixel PX3 and the fourth pixel PX4 on the third column C3. Further, the third plate patterns 124 may be disposed on the fourth column C4 which is adjacent to the second column C2 along the first direction DR1. For example, the third plate pattern 124 is disposed on one side of the second pixel PX2 or disposed on one side of the fourth pixel PX4 on the fourth column C4.

Each of the second line patterns 125 may be disposed on the active area AA of the lower substrate 111. The first and second power connection lines 131 and 132 for supplying the power voltage may be disposed on the second line patterns 125.

The second line patterns 125 are patterns which are disposed on the active area AA and connect the second plate patterns 123 which are adjacent to each other or the third plate patterns 124 which are adjacent to each other and are referred to as second connection patterns. At least one second line pattern 125 is disposed between the second plate patterns 123 or the third plate patterns 124.

For example, the second line patterns 125 are disposed on the third column C3 along the second direction DR2 between the second plate patterns 123 which are spaced apart from each other along the second direction DR2. Further, the second line patterns 125 are disposed on the fourth column C4 along the second direction DR2 between the third plate patterns 124 which are spaced apart from each other along the second direction DR2.

In one example embodiment, as illustrated in FIG. 7, each of the second line patterns 125 has a wavy shape. For example, the second line patterns 125 may have a sinusoidal shape. However, it is just illustrative, so that the shape of the second line pattern 125 is not limited thereto. For example, each of the second line patterns 125 may have a zigzag shape. As another example, each of the second line patterns 125 may have various shapes, such as a plurality of rhombic substrates being connected and extending at vertices. As described above, the shape of the second line patterns 125 illustrated in FIG. 7 is illustrative and the shape of the second line patterns 125 may vary depending on the design.

In one example embodiment, the second plate pattern 123, the third plate pattern 124, and the second line pattern 125 may be rigid patterns. For example, the second plate pattern 123, the third plate pattern 124, and the second line pattern 125 may be more rigid than the lower substrate 111 and the upper substrate 112. Accordingly, moduli of elasticity of the second plate pattern 123, the third plate pattern 124, and the second line pattern 125 may be higher than the modulus of elasticity of the lower substrate 111. Therefore, the second plate pattern 123, the third plate pattern 124, and the second line pattern 125 may be referred to as a third rigid pattern, a fourth rigid pattern, and a fifth rigid pattern. For example, moduli of elasticity the second plate pattern 123, the third plate pattern 124, and the second line pattern 125 may be 1000 times higher than the modulus of elasticity of the lower substrate 111 and the upper substrate 112, but it is illustrative and the example embodiment of the present disclosure is not limited thereto.

In the example embodiment, the second plate pattern 123, the third plate pattern 124, and the second line pattern 125 may include a plastic material having a lower flexibility than the lower substrate 111 and the upper substrate 112. For example, similarly to the first plate pattern 121 and the first line pattern 122, the second plate pattern 123, the third plate pattern 124, and the second line pattern 125 may include at least one material of polyimide (PI), polyacrylate, and polyacetate.

According to the example embodiment, the second plate pattern 123, the third plate pattern 124, and the second line pattern 125 may be formed of the same material, but are not limited thereto and may be formed of different materials. When the second plate pattern 123, the third plate pattern 124, and the second line pattern 125 are formed of the same material, the second plate pattern 123, the third plate pattern 124, and the second line pattern 125 may be integrally formed.

Further, in one example embodiment, the second plate pattern 123, the third plate pattern 124, and the second line pattern 125 are formed of the same material as the first plate pattern 121 and the first line pattern 122. In this case, all the plurality of plate patterns 121, 123, and 124 and the plurality of line patterns 122 and 125 which are formed on the active area AA may be integrally formed. That is, the plurality of plate patterns 121, 123, and 124 and the plurality of line patterns 122 and 125 may be formed with the same material by the same process during the manufacturing process of the display device 100.

The first and second power connection lines 131 and 132 are wiring lines for supplying a power voltage (for example, a high potential voltage and a low potential voltage) and are formed and/or disposed on the second plate pattern 123, the third plate pattern 124, and the second line pattern 125 which are disposed on the active area AA.

In one example, the first and second power connection lines 131 and 132 include a plurality of first power connection lines 131 and a plurality of second connection lines 132.

The first power connection lines 131 are disposed on the third column C3 along the second direction DR2 and are supplied with a high potential voltage VDD through the first power connection line 131. Further, the second power connection lines 132 are disposed on the fourth column C4 along the second direction DR2 and are supplied with a low potential voltage VSS through the second power connection line 132. That is, the first power connection lines 131 supplied with the high potential voltage VDD and the second power connection lines 132 supplied with the low potential voltage VSS are disposed between the pixels PX1 to PX4 on different columns C3 and C4. For example, the first power connection line 131 and the second power connection line 132 are alternately disposed along the first direction DR1.

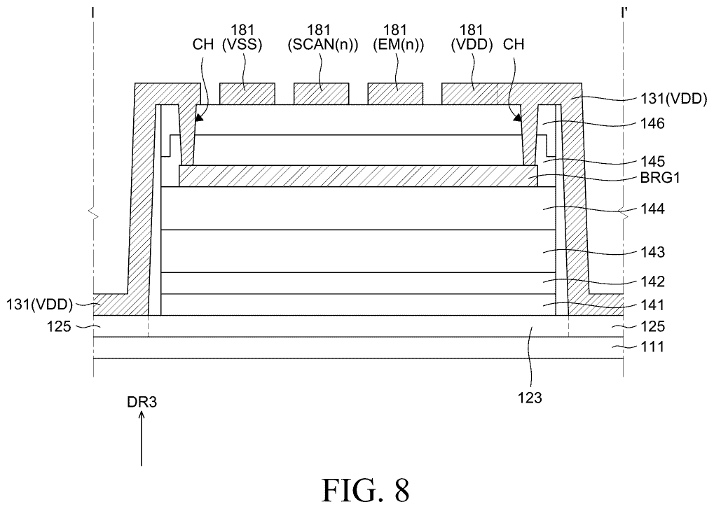

In one example embodiment, each of the first power connection lines 131 may be disposed on a corresponding second line pattern 125, among the second line patterns 125 disposed on the third column C3. Further, the first power connection lines 131 disposed on the second line patterns 125 which are disposed to be spaced apart from each other extend from the second line pattern 125 to a partial area of the second plate pattern 123 to be electrically connected to each other through a contact hole CH. For example, the first power connection lines 131 disposed on the second line patterns 125 are electrically connected to each other through a first bridge BRG1 (see FIG. 8) formed (or disposed) on the second plate pattern 123, through contact holes CH formed on one side or the other side of the second plate pattern 123.

Further, the first power connection lines 131 which are electrically connected to each other through the contact holes CH formed on the second plate pattern 123 are electrically connected to a first connection line 181 serving as a high potential voltage line which transmits the high potential voltage VDD, among the first connection lines 181, on the second plate pattern 123. For example, the first power connection lines 131 extend from the second line pattern 125 to the second plate pattern 123 corresponding to one side of the second plate pattern 123 on which the first connection line 181 transmitting a high potential voltage VDD is disposed, to be electrically connected to the first connection line 181 which transmits the high potential voltage VDD.

The first connection line 131 may be formed of a metal material such as copper (Cu), aluminum (Al), titanium (Ti), and molybdenum or a stacked structure of metal materials such as copper/molybdenum-titanium (Cu/Moti) or titanium/aluminum/titanium (Ti/Al/Ti), but is not limited thereto.

According to the example embodiment, the first power connection line 131 may include the same material as the connection lines 181 and 182. When the first power connection line 131 and the connection lines 181 and 182 include the same material, the first power connection lines 131 and the first connection line 181 which is electrically connected to the first power connection line 131 which transmits the high potential voltage VDD, among the first connection lines 181, are integrally formed by the same process.

In the meantime, the above-described first bridge BRG1 (see FIG. 8) is formed (or disposed) on the second plate pattern 123 and the first connection lines 181 which extend along the first direction DR1 on the second plate pattern 123 and the first bridge BRG1 (see FIG. 8) may be disposed on different layers. Therefore, the first bridge BRG1 (see FIG. 8) which is electrically connected to the first power connection line 131 supplying a high potential voltage VDD is suppressed from being connected to a first connection line 181 supplying a low potential voltage VSS, a first connection line 181 supplying a scan signal SCAN(n-1) or SCAN(n), and a first connection line 181 supplying an emission signal EM(n-1) or EM(n). Specific cross-sectional structures of the first connection lines 181, the first power connection lines 131, and the first bridge BRG1 (see FIG. 8) will be described in more detail with reference to FIG. 8.

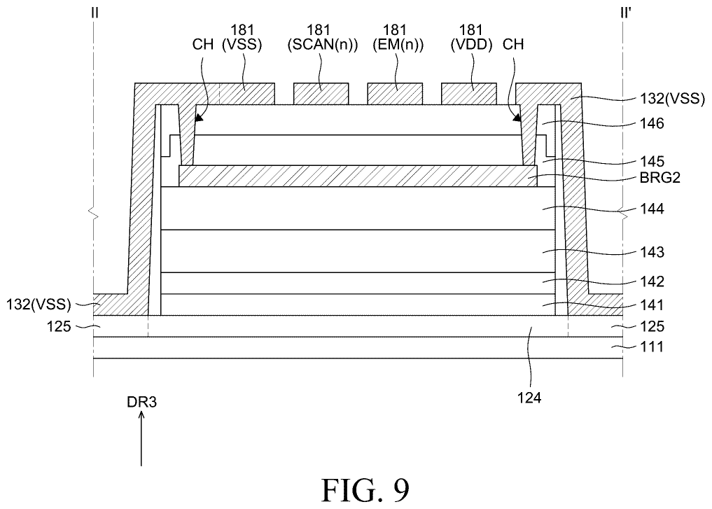

In one example embodiment, each of the second power connection lines 132 may be disposed on a corresponding second line pattern 125, among the second line patterns 125 disposed on the fourth column C4. Further, the second power connection lines 132 disposed on the second line patterns 125 which are disposed to be spaced apart from each other extend from the second line pattern 125 to a partial area of the third plate pattern 124 to be electrically connected to each other through a contact hole CH. For example, the second power connection lines 132 disposed on the second line patterns 125 are electrically connected to each other through a second bridge BRG2 (see FIG. 9) formed (or disposed) on the third plate pattern 124, through contact holes CH formed on one side or the other side of the third plate pattern 124.

Further, the second power connection lines 132 which are electrically connected to each other through the contact holes CH formed on the third plate pattern 124 are electrically connected to a first connection line 181 serving as a low potential voltage line which transmits the low potential voltage VSS, among the first connection lines 181, on the third plate pattern 124. For example, the second power connection lines 132 extend from the second line pattern 125 to the third plate pattern 124 corresponding to one side of the third plate pattern 124 on which the first connection line 181 transmitting a high potential voltage VDD is disposed, to be electrically connected to the first connection line 181 which transmits the low potential voltage VSS.

The second connection line 132 may be formed of a metal material such as copper (Cu), aluminum (Al), titanium (Ti), and molybdenum or a stacked structure of metal materials such as copper/molybdenum-titanium (Cu/Moti) or titanium/aluminum/titanium (Ti/Al/Ti), but is not limited thereto.

According to the example embodiment, the first power connection line 131 and the second power connection line 132 may include the same material.

Further, according to the example embodiment, the second power connection line 132 may include the same material as the connection lines 181 and 182. When the second power connection line 132 and the connection lines 181 and 182 include the same material, the second power connection lines 132 and the first connection line 181 which is electrically connected to the second power connection line 131 which transmits the low potential voltage VSS, among the first connection lines 181, are integrally formed by the same process.

In the meantime, the above-described second bridge BRG2 (see FIG. 9) is formed (or disposed) on the third plate pattern 124 and the first connection lines 181 which extend along the first direction DR1 on the third plate pattern 124 and the second bridge BRG2 (see FIG. 9) may be disposed on different layers. Therefore, the second bridge BRG2 (see FIG. 9) which is electrically connected to the second power connection line 132 supplying a low potential voltage VSS is suppressed from being connected to a first connection line 181 supplying a low potential voltage VSS, a first connection line 181 supplying a scan signal SCAN(n-1) or SCAN(n), and a first connection line 181 supplying an emission signal EM(n-1) or EM(n). Specific cross-sectional structures of the first connection lines 181, the second power connection lines 132, and the second bridge BRG2 (see FIG. 9) will be described in more detail with reference to FIG. 9.

Hereinafter, the placement relationship and cross-sectional structures of the first and second power connection lines 131 and 132, the first connection lines 181, and the bridges BRG1 and BRG2 will be described in more detail with further reference to FIGS. 8 and 9.

FIG. 8 is a cross-sectional view illustrating an example taken along the line I-I′ of FIG. 7.

FIG. 9 is a cross-sectional view illustrating an example taken along the line II-II′ of FIG. 7.

In the meantime, in FIGS. 8 and 9, in order to avoid the redundant description, parts which will not be specifically described follow the above description and the same reference numeral denotes the same component and the similar reference numeral denotes the similar component.

First, a placement relationship of the first power connection line 131, the first connection line 181, and the first bridge BRG1 will be described with reference to FIGS. 1 to 8. A plurality of second plate patterns 123 which is spaced apart from each other on the lower substrate 111 and the second line patterns 125 which connects the second plate patterns 123 are disposed. For example, the plurality of second plate patterns 123 is disposed on the third column C3 of the active area AA of the lower substrate 111 to be spaced apart from each other and the second connection lines 125 which connect the second plate patterns 123 are disposed on the third column C3.

An inorganic insulating layer may be disposed on the plurality of second plate patterns 123. For example, the inorganic insulating layer may include a buffer layer 141, a gate insulating layer 142, a first interlayer insulating layer 143, a second interlayer insulating layer 144, and a passivation layer 145. However, the example embodiment of the present disclosure is not limited thereto and various inorganic insulating layers are additionally disposed on the second plate patterns 123. At least one of the buffer layer 141, the gate insulating layer 142, the first interlayer insulating layer 143, the second interlayer insulating layer 144, and the passivation layer 145 which are inorganic insulating layers may be omitted.

To be more specific, the buffer layer 141 is disposed on the second plate patterns 123. The buffer layer 141 may include an insulating material. In one example embodiment, the buffer layer 141 may be formed only in an area where the lower substrate 111 overlaps a plurality of plate patterns (for example, first to third plate patterns 121, 123, and 124). As described above, the buffer layer 141 may be formed of an inorganic material so that the buffer layer 141 may be easily cracked or damaged during a process of stretching the display device 100. Therefore, the buffer layer 141 is not formed in an area between the plurality of plate patterns (for example, first to third plate patterns 121, 123, and 124). However, the buffer layer 131 is formed to have a shape of the plurality of plate patterns (for example, first to third plate patterns 121, 123, and 124) to be formed only above the plurality of plate patterns (for example, first to third plate patterns 121, 123, and 124). Therefore, in the display device 100 according to the example embodiment of the present disclosure, the buffer layer 141 is formed only in an area overlapping the plurality of plate patterns (for example, the first to third plate patterns 121, 123, and 124) which are rigid patterns. Therefore, even though the display device 100 is bent or extended to be deformed, the damage of various components of the display device 100 may be suppressed.

The gate insulating layer 142 may be disposed on the buffer layer 141. The gate insulating layer 142 may include an insulating material.

A first interlayer insulating layer 143 may be disposed on the gate electrode 142. The first interlayer insulating layer 143 may be formed of an inorganic material, similarly to the buffer layer 141. The second interlayer insulating layer 144 may be disposed on the first interlayer insulating layer 143. The second interlayer insulating layer 144 may include an inorganic material, which is the same as the buffer layer 141.

The first bridge BRG1 is disposed on the second interlayer insulating layer 144. The first bridge BRG1 may include any one of various metal materials, such as molybdenum (Mo), aluminum (Al), chrome (Cr), gold (Au), titanium (Ti), nickel (Ni), neodymium (Nd), and copper (Cu) or an alloy of two or more of them, or a multiple layer thereof, but it is not limited thereto.

In one example embodiment, the first bridge BRG1 may be disposed on the same layer as the source electrode 153 and the drain electrode 154 of the switching transistor 150 and the source electrode and the drain electrode 164 of the driving transistor 160, which have been described with references to FIGS. 1 to 6. That is, the first bridge BRG1 may be disposed on the same second interlayer insulating layer 144 as the source electrode 153 and the drain electrode 154 of the switching transistor 150 and the source electrode and the drain electrode 164 of the driving transistor 160. Further, the first bridge BRG1 includes the same material as the source electrode 153 and the drain electrode 154 of the switching transistor 150 and the source electrode and the drain electrode 164 of the driving transistor 160. In this case, the first bridge BRG1 may be formed by the same process as the source electrode 153 and the drain electrode 154 of the switching transistor 150 and the source electrode and the drain electrode 164 of the driving transistor 160.

The passivation layer 145 is formed on the first bridge BRG1. For example, the passivation layer 145 may be disposed so as to cover the first bridge BRG1. The passivation layer 145 may include an inorganic material and be configured by a single layer or a double layer, but is not limited thereto.

The gate insulating layer 142, the first interlayer insulating layer 143, the second interlayer insulating layer 144, and the passivation layer 145 are patterned to be formed only in an area overlapping the plurality of plate patterns (for example, first to third plate patterns 121, 123, and 124). The gate insulating layer 142, the first interlayer insulating layer 143, the second interlayer insulting layer 144, and the passivation layer 145 are also formed of the inorganic material, similar to the buffer layer 141. Therefore, the gate insulating layer 142, the first interlayer insulating layer 143, the second interlayer insulating layer 144, and the passivation layer 145 may also be easily cracked to be damaged during the process of stretching the display device 100. Therefore, the gate insulating layer 142, the first interlayer insulating layer 143, the second interlayer insulting layer 144, and the passivation layer 145 are not formed in an area between the plurality of plate patterns (for example, first to third plate patterns 121, 123, and 124). However, the gate insulating layer 142, the first interlayer insulating layer 143, the second interlayer insulating layer 144, and the passivation layer 145 are patterned with a shape of the plurality of plate patterns (for example, first to third plate patterns 121, 123, and 124) to be formed only above the plurality of plate patterns (for example, first to third plate patterns 121, 123, and 124).

The planarization layer 146 is formed on the passivation layer 145. The planarization layer 146 may planarize upper portions of components disposed therebelow.

The first connection lines 181 which have been described with reference to FIGS. 1 to 7 are disposed on the planarization layer 146. For example, a first connection line 181 configured to supply the low potential voltage VSS, a first connection line 181 configured to supply the scan signal SCAN(n), a first connection line 181 configured to supply the emission signal EM(n), and a first connection line 181 configured to supply the high potential voltage VDD are disposed on the planarization layer 146 to be spaced apart from each other. For example, as illustrated in FIG. 7, the first connection line 181 configured to supply the low potential voltage VSS, the first connection line 181 configured to supply the scan signal SCAN(n), the first connection line 181 configured to supply the emission signal EM(n), and the first connection line 181 configured to supply the high potential voltage VDD may be sequentially disposed along the second direction DR2 to be spaced apart from each other.

The first power connection lines 131 are disposed on the second line patterns 125. The first power connection lines 131 may also extend onto the second plate patterns 123 so as to be electrically connected to the first connection line 181 configured to supply the high potential voltage VDD on the second plate pattern 123. In the meantime, the first power connection lines 131 may be disposed so as not to be connected to the first connection line 181 configured to supply the low potential voltage VSS, the first connection line 181 configured to supply the scan signal SCAN(n), and the first connection line 181 configured to supply the emission signal EM(n).

In one example embodiment, as illustrated in FIGS. 7 and 8, the first power connection lines 131 disposed on both sides of the second plate pattern 123 may be electrically connected to each other through contact holes formed on both sides of the second plate pattern 123. For example, the first power connection line 131 disposed on one side of the second plate pattern 123 is electrically connected to the first bridge BRG1 through a contact hole CH formed in one side of the second plate pattern 123. The first power connection line 131 disposed on the other side of the second plate pattern 123 is electrically connected to the first bridge BRG1 through a contact hole CH formed in the other side of the second plate pattern 123. By doing this, the first connection lines 131 disposed on both sides of the second plate pattern 123 are electrically connected to each other. Therefore, the high potential voltage VDD is transmitted through the first power connection lines 131.

Next, a placement relationship of the second power connection line 132, the first connection line 181, and the second bridge BRG2 will be described with reference to FIGS. 1 to 7 and 9. A plurality of third plate patterns 124 which is spaced apart from each other on the lower substrate 111 and the second line patterns 125 which connects the third plate patterns 124 are disposed. For example, the plurality of third plate patterns 124 is disposed on the fourth column C4 of the active area AA of the lower substrate 111 to be spaced apart from each other and the second line patterns 125 which connect the third plate patterns 124 are disposed on the fourth column C4.

An inorganic insulating layer may be disposed on the plurality of third plate patterns 124 as described with reference to FIG. 8. For example, the buffer layer 141, the gate insulating layer 142, the first interlayer insulating layer 143, and the second interlayer insulating layer 144 may be disposed on the plurality of third plate patterns 124.

The second bridge BRG2 is disposed on the second interlayer insulating layer 144. The second bridge BRG2 may include any one of various metal materials, such as molybdenum (Mo), aluminum (Al), chrome (Cr), gold (Au), titanium (Ti), nickel (Ni), neodymium (Nd), and copper (Cu) or an alloy of two or more of them, or a multiple layer thereof, but it is not limited thereto.

In one example embodiment, the second bridge BRG2 may be disposed on the same layer as the source electrode 153 and the drain electrode 154 of the switching transistor 150 and the source electrode and the drain electrode 164 of the driving transistor 160, which have been described with references to FIGS. 1 to 6. That is, the second bridge BRG2 may be disposed on the same second interlayer insulating layer 144 as the source electrode 153 and the drain electrode 154 of the switching transistor 150 and the source electrode and the drain electrode 164 of the driving transistor 160. Further, the second bridge BRG2 includes the same material as the source electrode 153 and the drain electrode 154 of the switching transistor 150 and the source electrode and the drain electrode 164 of the driving transistor 160. In this case, the second bridge BRG2 may be formed by the same process as the source electrode 153 and the drain electrode 154 of the switching transistor 150 and the source electrode and the drain electrode 164 of the driving transistor 160.

According to the example embodiment, the first bridge BRG1 (see FIG. 8) and the second bridge BRG2 include the same material and are formed on the same layer.

The passivation layer 145 is formed on the second bridge BRG2 and the planarization layer 146 is formed on the passivation layer 145.

The first connection lines 181 which have been described with reference to FIGS. 1 to 7 are disposed on the planarization layer 146. For example, a first connection line 181 configured to supply the low potential voltage VSS, a first connection line 181 configured to supply the scan signal SCAN(n), a first connection line 181 configured to supply the emission signal EM(n), and a first connection line 181 configured to supply the high potential voltage VDD are disposed on the planarization layer 146 to be spaced apart from each other. For example, as illustrated in FIG. 7, the first connection line 181 configured to supply the low potential voltage VSS, the first connection line 181 configured to supply the scan signal SCAN(n), the first connection line 181 configured to supply the emission signal EM(n), and the first connection line 181 configured to supply the high potential voltage VDD may be sequentially disposed along the second direction DR2 to be spaced apart from each other.

The second power connection lines 132 are disposed on the second line patterns 125. The second power connection lines 132 may also extend onto the third plate patterns 124 so as to be electrically connected to the first connection line 181 configured to supply the low potential voltage VSS on the third plate pattern 124. In the meantime, the second power connection lines 132 may be disposed so as not to be connected to the first connection line 181 configured to supply the high potential voltage VDD, the first connection line 181 configured to supply the scan signal SCAN(n), and the first connection line 181 configured to supply the emission signal EM(n).

In one example embodiment, as illustrated in FIGS. 7 and 9, the second power connection lines 132 disposed on both sides of the third plate pattern 124 may be electrically connected to each other through contact holes formed on both sides of the third plate pattern 124. For example, the second power connection line 132 disposed on one side of the third plate pattern 124 is electrically connected to the second bridge BRG2 through a contact hole CH formed in one side of the third plate pattern 124. The second power connection line 132 disposed on the other side of the third plate pattern 124 is electrically connected to the second bridge BRG2 through a contact hole CH formed in the other side of the third plate pattern 124. By doing this, the second connection lines 132 disposed on both sides of the third plate pattern 124 are electrically connected to each other. Therefore, the low potential voltage VSS is transmitted through the second power connection lines 132.

As described with reference to FIGS. 1 to 9, as a wiring line for supplying a power voltage (for example, a high potential voltage VDD and a low potential voltage VSS), first and second power connection lines 131 and 132 are disposed on the active area AA. For example, in the case of the display device 100 according to the example embodiments of the present disclosure, the first power connection line 131 for supplying the high potential voltage VDD to the pixels PX and the second power connection line 132 for supplying the low potential voltage VSS may be disposed on the active area AA, rather than the non-active area NA. By doing this, a bezel area of the display device 100 may be reduced.

Further, as illustrated in FIG. 7, the first power connection lines 131 for supplying the high potential voltage VDD to the pixels PX and the first connection line 181 are connected to each other to be entirely disposed in a mesh pattern. Similarly, the second power connection lines 132 for supplying the low potential voltage VDD to the pixels PX and the first connection line 181 are connected to each other to be entirely disposed in a mesh pattern. As described above, wiring lines for supplying a power voltage are disposed on the active area AA in the mesh pattern so that the deviation of the power voltage on the active area AA due to the internal resistance of the wiring line are reduced. Therefore, the luminance uniformity is improved and the display device with a high resolution and a large size may be implemented.

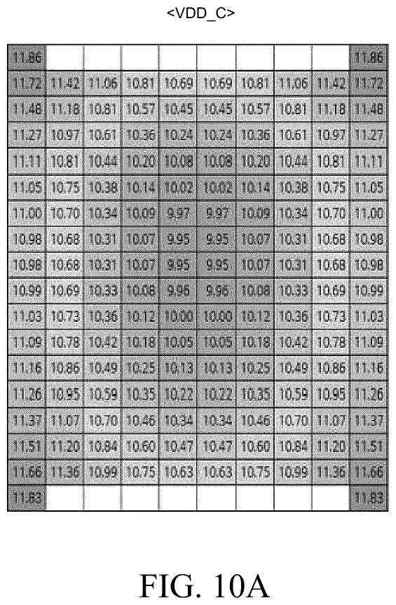

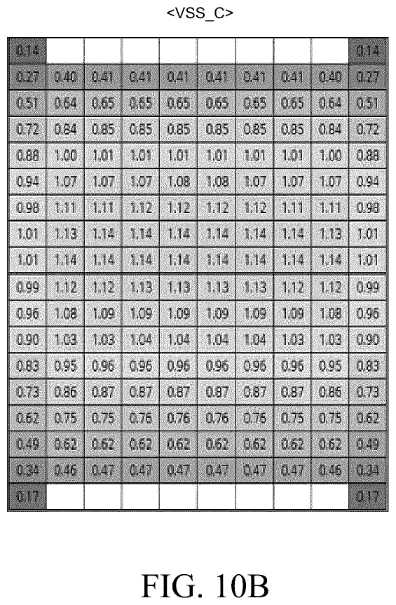

FIGS. 10A and 10B are views for explaining a deviation of a power voltage due to an internal resistance of a display device according to Comparative Example of the present disclosure.

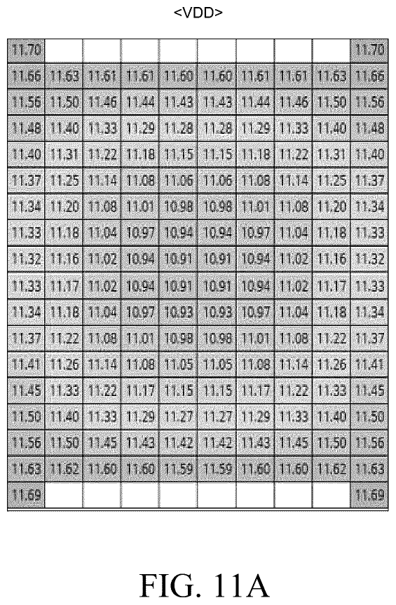

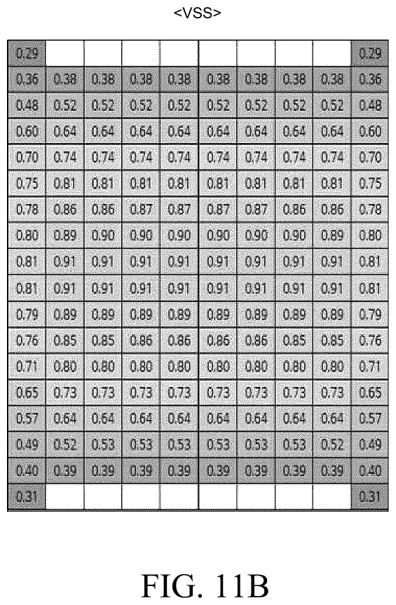

FIGS. 11A and 11B are views for explaining a deviation of a power voltage due to an internal resistance of a display device according to example embodiments of the present disclosure.

In the meantime, in FIGS. 10A and 10B, in a display device according to Comparative Example in which wiring lines for supplying a power voltage are disposed on the non-active area (for example, both sides of the active area), values of high potential voltages VDD_C and values of low potential voltages VSS_C for every active area are illustrated. In FIGS. 11A and 11B, in a display device 100 according to the example embodiments of the present disclosure in which wiring lines for supplying a power voltage (for example, first and second power connection lines 131 and 132) are disposed on the active area, values of high potential voltages VDD and values of low potential voltages VSS for every active area AA are illustrated.

Referring to FIGS. 10A and 10B, in the case of the display device according to Comparative Example of the present disclosure, a difference between the high potential voltage VDD_C and the low potential voltage VSS_C according to an internal resistance of a wiring line for providing a power voltage may be relatively large according to a relative position of the active area. For example, in the case of the high potential voltage VDD_C, a difference of a greatest value (11.86 V) and a smallest value (9.95 V) on the active area is 1.91 V and in the case of the low high potential voltage VSS_C, a difference of a greatest value (1.14 V) and a smallest value (0.14 V) on the active area is 1.00 V. As described above, in the case of the display device according to Comparative Example, a deviation of the high potential voltage VDD_C and a deviation of the low potential voltage VSS_C may be relatively large according to the active area.

In contrast, referring to FIGS. 11A and 11B, in the case of the display device 100 according to the example embodiments of the present disclosure, a difference between the high potential voltage VDD and the low potential voltage VSS according to an internal resistance of a wiring line for providing a power voltage may be relatively small according to a relative position of the active area AA. For example, in the case of the high potential voltage VDD, a difference of a greatest value (11.70 V) and a smallest value (10.91 V) on the active area AA is 0.79 V and in the case of the low high potential voltage VSS, a difference of a greatest value (0.91 V) and a smallest value (0.29 V) on the active area AA is 0.62 V. As described above, in the display device 100 according to the example embodiments of the present disclosure, as compared with the display device according to Comparative Example which has been described with reference to FIGS. 10A and 10B, a deviation of the high potential voltage VDD and a deviation of the low potential voltage VSS according to the active area AA may be relatively small.

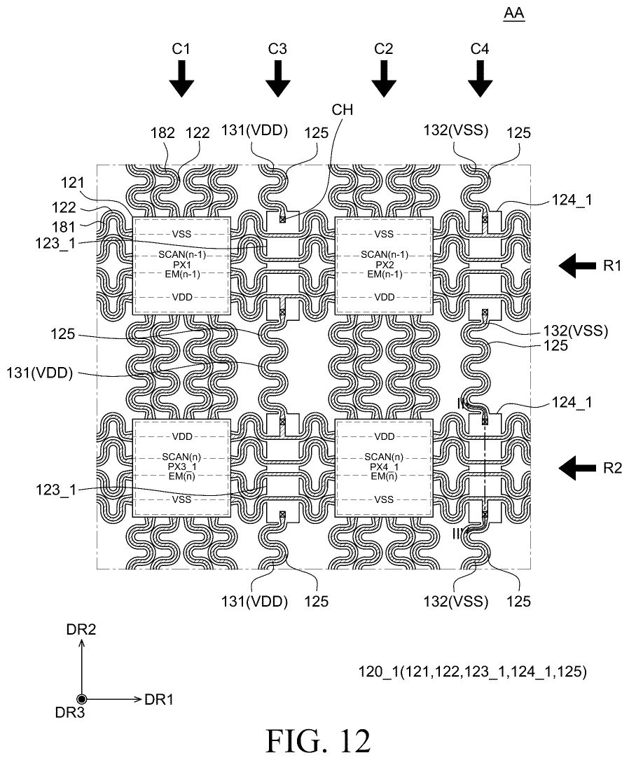

FIG. 12 is a view illustrating another example of a placement relationship between a pixel and connection lines included in a display device of FIG. 1.

In the meantime, in FIG. 12, for the convenience of description, only four pixels PX1, PX2, PX3_1, and PX4_1, among pixels PX disposed on the active area AA of the display device 100 are illustrated.

In the meantime, FIG. 12 illustrates a modified example of the example embodiment which has been described with reference to FIGS. 1 to 9, with regard to the placement shapes of pixels PX1, PX2, PX3_1, and PX4_1 and a connection relationship of the first connection lines 181 and the first and second power connection lines 131 and 132. In order to avoid the redundant description, the difference from the above-described example embodiment will be mainly described and parts which will not be specifically described follow the above-described example embodiment. The same reference numeral denotes the same component and the similar reference numeral denotes similar component.

Referring to FIGS. 1 to 6 and 12, pixels PX1, PX2, PX3_1, and PX4_1 are disposed to be spaced apart from each other. For example, in a first row R1, first and second pixels PX1 and PX2 are sequentially disposed along the first direction DR1 to be spaced apart from each other. Further, in a second row R2, the third and fourth pixels PX3_1 and PX4_1 are sequentially disposed along the first direction DR1 to be spaced apart from each other. As another example, in a first column C1, first and third pixels PX1 and PX3_1 are sequentially disposed along the second direction DR2 to be spaced apart from each other. Further, in a second column C2, the second and fourth pixels PX2 and PX4_1 are sequentially disposed along the second direction DR2 to be spaced apart from each other.

Further, as described with reference to FIGS. 1 to 6, the pixels PX1, PX2, PX3_1, and PX4_1 disposed on the first plate pattern 121 are electrically connected to the first line pattern 122 and the connection lines 181 and 182 to be supplied with various signals and various voltages. For example, various signals include a scan signal, an emission signal, and a data signal and various voltages include a high potential voltage, a low potential voltage, and an initialization voltage.

In one example embodiment, the pixels PX1, PX2, PX3_1, and PX4_1 disposed in the active area AA may be symmetrically disposed to each other with respect to a reference line parallel to the first direction DR1. For example, the pixels PX1, PX2, PX3_1, and PX4_1 may be disposed in a flip type to be opposite to each other. For example, pixels disposed in an odd-numbered pixel row and pixels disposed in an even-numbered pixel row are symmetrical to each other to be opposite to each other. For example, the first and second pixels PX1 and PX2 disposed in the first row R1 and the third and fourth pixels PX3_1 and PX4_1 disposed in the second row R2 may be disposed to be symmetrical to each other. Therefore, the signals and the power voltages are applied in the order of the low potential voltage VSS, the scan signal SCAN(n-1) or SCAN(n), the emission signal EM(n-1) or EM(n), and the high potential voltage VDD, to the first connection lines 181 connected to the first and second pixels PX1 and PX2 disposed in the first row R1 along the second direction DR2. Further, the signals and the power voltages are applied in the order of the high potential voltage VDD, the scan signal SCAN(n-1) or SCAN(n), the emission signal EM(n-1) or EM(n), and the low potential voltage VSS, to the first connection lines 181 connected to the third and fourth pixels PX3_1 and PX4_1 disposed in the second row R2 along the second direction DR2. In other words, the first connection line 181 serving as the high potential voltage line, the first connection line 181 serving as the low potential voltage line, the first connection line 181 serving as the scan signal line, and the first connection line 181 serving as the emission signal line may be disposed in the first row R1 and the second row R2 to be opposite.

Further, in the case of the display device 100 according to the example embodiments of the present disclosure, as a wiring line for supplying a power voltage (for example, a high potential voltage VDD and a low potential voltage VSS), first and second power connection lines 131 and 132 are disposed on the active area AA.

In order to dispose the first and second power connection lines 131 and 132 on the active area AA, in one example embodiment, a pattern layer 120_1 included in the display device 100 further includes a plurality of second plate patterns 123_1, a plurality of third plate patterns 124_1, and a plurality of second line patterns 125.

In the meantime, in the example embodiment of FIG. 12, pixels PX1 and PX2 disposed in the first row R1 and pixels PX3_1 and PX4_1 disposed in the second row R2 are symmetrically disposed to be opposite to each other. Therefore, except a position in which the first power connection line 131 which is disposed in the second line pattern 125 to supply the high potential voltage VDD is integrally formed with the first connection line 181 serving as the high potential voltage line to be connected on the second plate pattern 123_1 and a position in which the second power connection line 132 which is disposed in the second line pattern 125 to supply the low potential voltage VSS is integrally formed with the first connection line 181 serving as the low potential voltage line to be connected on the third plate pattern 124_1, the other configurations are the same as that in the example embodiment which has been described with reference to FIGS. 7 to 9. Therefore, a redundant description will not be repeated.

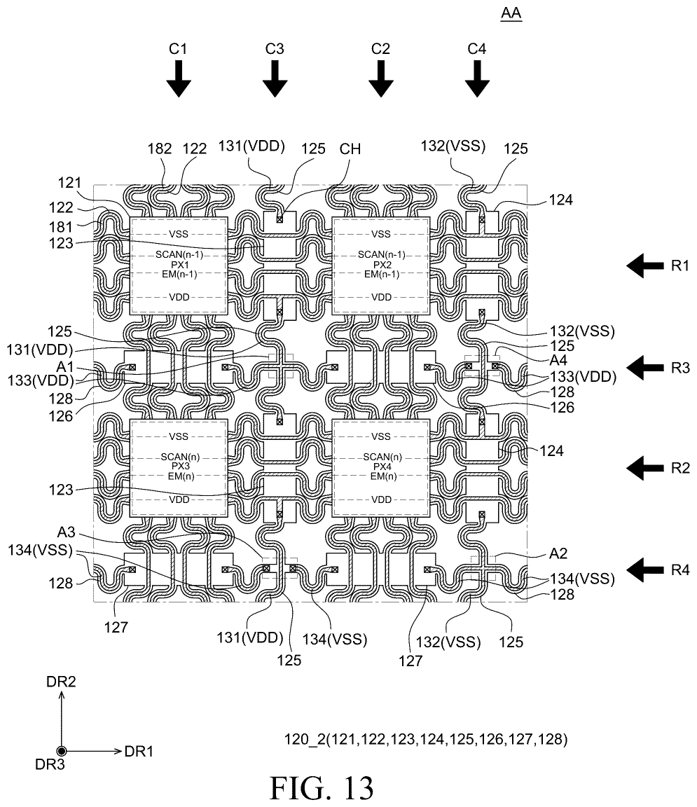

FIG. 13 is a view illustrating still another example of a placement relationship between a pixel and connection lines included in a display device of FIG. 1.

In the meantime, in FIG. 13, for the convenience of description, only four pixels PX1, PX2, PX3, and PX4, among pixels PX disposed on the active area AA of the display device 100 are illustrated.

In the meantime, FIG. 13 illustrates a modified example of the example embodiment which has been described with reference to FIGS. 1 to 9, with regard to a fourth plate pattern 126, a fifth plate pattern 127, a third line pattern 128 disposed on the active area AA, and third and fourth power connection lines 133 and 134 disposed thereon. In order to avoid the redundant description, the difference from the above-described example embodiment will be mainly described and parts which will not be specifically described follow the above-described example embodiment. The same reference numeral denotes the same component and the similar reference numeral denotes similar component.

Referring to FIGS. 1 to 6 and 13, in the case of the display device 100 according to the example embodiments of the present disclosure, third and fourth power connection lines 133 and 134 for supplying a power voltage (for example, a high potential voltage VDD and a low potential voltage VSS) may be further disposed on the active area AA.

In order to dispose the third and fourth power connection lines 133 and 134 on the active area AA, in one example embodiment, a pattern layer 120_2 included in the display device 100 further includes a plurality of fourth plate patterns 126, a plurality of fifth plate patterns 127, and a plurality of third line patterns 128.

The fourth plate patterns 126 and the fifth plate patterns 127 may be disposed on the active area AA of the lower substrate 111. On the fourth plate patterns 126 and the fifth plate patterns 127, some of the third and fourth power connection lines 133 and 134 for supplying the power voltage and some of the second connection lines 182 disposed along the second direction DR2 may be disposed.

In one example embodiment, the fourth plate patterns 126 are disposed as islands shapes which are spaced apart from each other. Similarly, the fifth plate patterns 127 are disposed as islands shapes which are spaced apart from each other.

Further, each of the fourth plate patterns 126 and each of the fifth plate patterns 127 may have a rectangular shape elongated along the first direction DR1 which is the same as the extending direction of the third and fourth power connection lines 133 and 134. For example, each of the fourth plate patterns 126 and each of the fifth plate patterns 127 have a rectangular shape in which long sides are parallel to the first direction DR1 and short sides are parallel to the second direction DR2.

In one example embodiment, each of the fourth plate patterns 126 may be disposed in an area between the first plate patterns 121 so as not to overlap the first plate patterns 121 in which the pixels PX1 to PX4 are disposed. Similarly, each of the fifth plate patterns 127 may be disposed in an area between the first plate patterns 121 so as not to overlap the first plate patterns 121 in which the pixels PX1 to PX4 are disposed.

For example, the fourth plate patterns 126 may be disposed on the third row R3 which is adjacent to the first row R1 along the second direction DR2 and is disposed between the first row R1 and the second row R2. For example, the fourth plate pattern 126 may be disposed between the first pixel PX1 and the third pixel PX3 or between the second pixel PX2 and the fourth pixel PX4 on the third row R3. Further, the fifth plate patterns 127 may be disposed on the fourth row R4 which is adjacent to the second row R2 along the second direction DR2. For example, the fifth plate pattern 127 is disposed on one side of the third pixel PX3 or disposed on one side of the fourth pixel PX4 on the fourth row R4.

Each of the third line patterns 128 may be disposed on the active area AA of the lower substrate 111. The third and fourth power connection lines 133 and 134 for supplying the power voltage may be disposed on the third line patterns 128.

The third line patterns 128 are patterns which are disposed on the active area AA and connect the fourth plate patterns 126 which are adjacent to each other or the fifth plate patterns 127 which are adjacent to each other and are referred to as third connection patterns. That is, at least one third line pattern 128 is disposed between the fourth plate patterns 126 or the fifth plate patterns 127.

For example, the third line patterns 128 are disposed on the third row R3 along the first direction DR1 between the fourth plate patterns 126 which are spaced apart from each other along the first direction DR1. Further, the third line patterns 128 are disposed on the fourth row R4 along the first direction DR1 between the fifth plate patterns 127 which are spaced apart from each other along the first direction DR1.

In one example embodiment, as illustrated in FIG. 13, each of the third line patterns 128 has a wavy shape. For example, the third line patterns 128 may have a sinusoidal shape. However, it is just illustrative, so that the shape of the third line pattern 128 is not limited thereto. For example, each of the third line patterns 128 may have a zigzag shape. As another example, each of the third line patterns 128 may have various shapes, such as a plurality of rhombic substrates being connected and extending at vertices. As described above, the shape of the third line patterns 128 illustrated in FIG. 13 is illustrative and the shape of the third line patterns 128 may vary depending on the design.

In one example embodiment, the fourth plate pattern 126, the fifth plate pattern 127, and the third line pattern 128 may be rigid patterns. For example, the fourth plate pattern 126, the fifth plate pattern 127, and the third line pattern 128 may be more rigid than the lower substrate 111 and the upper substrate 112. Accordingly, moduli of elasticity of the fourth plate pattern 126, the fifth plate pattern 127, and the third line pattern 128 may be higher than the modulus of elasticity of the lower substrate 111. Therefore, the fourth plate pattern 126, the fifth plate pattern 127, and the third line pattern 128 may be referred to as a sixth rigid pattern, a seventh rigid pattern, and an eighth rigid pattern. For example, moduli of elasticity the fourth plate pattern 126, the fifth plate pattern 127, and the third line pattern 128 may be 1000 times higher than the modulus of elasticity of the lower substrate 111 and the upper substrate 112, but it is illustrative and the example embodiment of the present disclosure is not limited thereto.

In the example embodiment, the fourth plate pattern 126, the fifth plate pattern 127, and the third line pattern 128 may include a plastic material having a lower flexibility than the lower substrate 111 and the upper substrate 112. For example, similarly to the first plate pattern 121 and the first line pattern 122, the fourth plate pattern 126, the fifth plate pattern 127, and the third line pattern 128 may include at least one material of polyimide (PI), polyacrylate, and polyacetate.

According to the example embodiment, the fourth plate pattern 126, the fifth plate pattern 127, and the third line pattern 128 may be formed of the same material, but are not limited thereto and may be formed of different materials. When the fourth plate pattern 126, the fifth plate pattern 127, and the third line pattern 128 are formed of the same material, the fourth plate pattern 126, the fifth plate pattern 127, and the third line pattern 128 may be integrally formed.

Further, in one example embodiment, the fourth plate pattern 126, the fifth plate pattern 127, and the third line pattern 128 are formed of the same material as the first to third plate patterns 121, 123, and 124 and the first and second line patterns 122 and 125. In this case, all the plurality of plate patterns 121, 123, 124, 126, and 127 and the plurality of line patterns 122, 125, and 128 which are formed on the active area AA may be integrally formed. That is, the plurality of plate patterns 121, 123, 124, 126, and 127 and the plurality of line patterns 122, 125, and 128 may be formed with the same material by the same process during the manufacturing process of the display device 100.

The third and fourth power connection lines 133 and 134 are wiring lines for supplying a power voltage (for example, a high potential voltage and a low potential voltage) and are formed and/or disposed on the fourth plate pattern 126, the fifth plate pattern 127, and the third line pattern 128 which are disposed on the active area AA.

In one example, the third and fourth power connection lines 133 and 134 include a plurality of third power connection lines 133 and a plurality of fourth connection lines 134.

The third power connection lines 133 is disposed on the third row R3 along the first direction DR1 and is supplied with a high potential voltage VDD through the third power connection line 133. Further, the fourth power connection lines 134 are disposed on the fourth row R4 along the first direction DR1 and are supplied with a low potential voltage VSS through the fourth power connection line 134. That is, the third power connection lines 133 supplied with the high potential voltage VDD and the fourth power connection lines 134 supplied with the low potential voltage VSS are disposed between the pixels PX1 to PX4 on different rows R3 and R4. For example, the third power connection line 133 and the fourth power connection line 134 are alternately disposed along the second direction DR2.

In one example embodiment, each of the third power connection lines 133 may be disposed on a corresponding third line pattern 128, among the third line patterns 128 disposed on the third row R3. Further, the third power connection lines 133 disposed on the third line patterns 128 which are disposed to be spaced apart from each other extend from the third line pattern 128 to a partial area of the fourth plate pattern 126 to be electrically connected to each other through a contact hole CH. For example, the third power connection lines 133 disposed on the third line patterns 128 are electrically connected to each other through a third bridge BRG3 formed (or disposed) on the fourth plate pattern 126, through contact holes CH formed on one side or the other side of the fourth plate pattern 126. The configuration in which the third power connection lines 133 are electrically connected to each other through the third bridge is substantially the same as or similar to the configuration in which the first power connection lines 131 are electrically connected to each other through the first bridge or the configuration in which the second power connection lines 132 are electrically connected to each other through the second bridge BRG2, as described with reference to FIGS. 7 to 9. Therefore, a redundant description will not be repeated.

The third connection line 133 may be formed of a metal material such as copper (Cu), aluminum (Al), titanium (Ti), and molybdenum or a stacked structure of metal materials such as copper/molybdenum-titanium (Cu/Moti) or titanium/aluminum/titanium (Ti/Al/Ti), but is not limited thereto.

According to the example embodiment, the third power connection line 133 may include the same material as the connection lines 181 and 182.

In the meantime, the above-described third bridge is formed (or disposed) on the fourth plate pattern 126 and the second connection lines 182 which extend along the second direction DR2 on the fourth plate pattern 126 and the third bridge may be disposed on different layers. Therefore, the third bridge which is electrically connected to the third power connection line 133 configured to supply the high potential voltage VDD is suppressed from being connected to the second connection line 182 configured to supply the data signal and the second connection line 182 configured to supply the initialization voltage.

In one example embodiment, each of the fourth power connection lines 134 may be disposed on a corresponding third line pattern 128, among the third line patterns 128 disposed on the fourth row R4. Further, the fourth power connection lines 134 disposed on the third line patterns 128 which are disposed to be spaced apart from each other extend from the third line pattern 128 to a partial area of the fifth plate pattern 127 to be electrically connected to each other through a contact hole CH. For example, the fourth power connection lines 134 disposed on the third line patterns 128 are electrically connected to each other through a fourth bridge formed (or disposed) on the fifth plate pattern 127, through contact holes CH formed on one side or the other side of the fifth plate pattern 127. The configuration in which the fourth power connection lines 134 are electrically connected to each other through the fourth bridge is substantially the same as or similar to the configuration in which the first power connection lines 131 are electrically connected to each other through the first bridge or the configuration in which the second power connection lines 132 are electrically connected to each other through the second bridge BRG2, as described with reference to FIGS. 7 to 9. Therefore, a redundant description will not be repeated.

The fourth connection line 134 may be formed of a metal material such as copper (Cu), aluminum (Al), titanium (Ti), and molybdenum or a stacked structure of metal materials such as copper/molybdenum-titanium (Cu/Moti) or titanium/aluminum/titanium (Ti/Al/Ti), but is not limited thereto.

According to the example embodiment, the fourth power connection line 134 may include the same material as the connection lines 181 and 182.

According to the example embodiment, the third power connection line 133 and the fourth power connection line 134 may include the same material.

In the meantime, the above-described fourth bridge is formed (or disposed) on the fifth plate pattern 127 and the second connection lines 182 which extend along the second direction DR2 on the fifth plate pattern 127 and the fourth bridge may be disposed on different layers. Therefore, the fourth bridge which is electrically connected to the fourth power connection line 134 configured to supply the low potential voltage VSS is suppressed from being connected to the second connection line 182 configured to supply the data signal and the second connection line 182 configured to supply the initialization voltage.

In one example embodiment, the third power connection line 133 configured to supply a high potential voltage VDD is connected to the first power connection line 131 in a first area A1. The fourth power connection line 134 configured to supply the low potential voltage VSS is connected to the second power connection line 132 in a second area A2.

For example, in the first area A1 corresponding to an area between the adjacent second plate patterns 123 and the adjacent fourth plate patterns 126, the first power connection line 131 and the third power connection line 133 which supply the high potential voltage VDD may intersect. Further, in the first area A1, the second line pattern 125 in which the first power connection line 131 is disposed and the third line pattern 128 in which the third power connection line 133 is disposed may intersect. In this case, the first power connection line 131 and the third power connection line 133 which supply the high potential voltage VDD are electrically connected to each other in the first area A1.

According to the example embodiment, in the first area A1, the second line pattern 125 in which the first power connection line 131 is disposed and the third line pattern 128 in which the third power connection line 133 is disposed are integrally formed. Further, the first power connection line 131 and the third power connection line 133 which supply the high potential voltage VDD are also integrally formed.

Further, in the second area A2 corresponding to an area between the adjacent third plate patterns 124 and the adjacent fifth plate patterns 127, the second power connection line 132 and the fourth power connection line 134 which supply the low potential voltage VSS may intersect. Further, in the second area A2, the second line pattern 125 in which the second power connection line 132 is disposed and the third line pattern 128 in which the fourth power connection line 134 is disposed may intersect. In this case, the second power connection line 132 and the fourth power connection line 134 which supply the low potential voltage VSS are electrically connected to each other in the second area A2.

According to the example embodiment, in the second area A2, the second line pattern 125 in which the second power connection line 132 is disposed and the third line pattern 128 in which the fourth power connection line 134 is disposed are integrally formed. Further, the second power connection line 132 and the fourth power connection line 134 which supply the low potential voltage VSS are also integrally formed.

In the meantime, as illustrated in FIG. 13, in a third area A3 corresponding to an area between adjacent second plate patterns 123 and adjacent fifth plate patterns 127, the third power connection line 133 is connected through a bridge disposed on a layer different from a layer on which the second power connection line 132 is disposed, on the third line pattern 128. Therefore, the electrical connection of the third power connection line 133 configured to supply the high potential voltage VDD and the second power connection line 132 configured to supply the low potential voltage VSS may be supplied. Similarly, in a fourth area A4 corresponding to an area between adjacent third plate patterns 124 and adjacent fourth plate patterns 126, the fourth power connection line 134 is connected through a bridge disposed on a layer different from a layer on which the first power connection line 131 is disposed, on the third line pattern 128. Therefore, the electrical connection of the fourth power connection line 134 configured to supply the low potential voltage VSS and the first power connection line 131 configured to supply the high potential voltage VDD may be supplied.

As described with reference to FIG. 13, in the case of the display device 100 according to the example embodiments of the present disclosure, not only the first and second power connection lines 131 and 132 which are disposed along the second direction DR2 on the active area, but also the third and fourth power connection lines 133 and 134 disposed along the first direction DR1 on the active area AA are further disposed. therefore, when the power voltage is supplied to the pixels PX1 to PX4, the deviation of the power voltage due to the internal resistance may be further reduced (for example, reduced).

As described above, the display device according to the example embodiments of the present disclosure includes power connection lines disposed on an active area as wiring lines for supplying a power voltage (for example, a high potential voltage and a low potential voltage). Therefore, a bezel area corresponding to a non-active area of the display device may be reduced.

According to the example embodiments of the present disclosure, in the display device, power connection lines for supplying a power voltage to pixels are disposed in a mesh pattern as a whole. Accordingly, a deviation of the power voltage due to the internal resistance of the wiring line may be reduced so that the luminance uniformity is improved and a display device with a high luminance and a large size may be implemented.

The example embodiments of the present disclosure can also be described as follows:

According to an aspect of the present disclosure, a display device includes a lower substrate which includes an active area and a non-active area and is stretchable; a pattern layer which is disposed on the active area of the lower substrate and includes a plurality of first plate patterns and a plurality of first line patterns; a plurality of pixels which is disposed on each of the plurality of first plate patterns; a plurality of connection lines which is disposed on the plurality of first line patterns and configured to connect the pixels; and a plurality of power connection lines configured to supply a power voltage to the pixels, and the power connection lines are disposed between the pixels on the active area.

The pixels may include a first pixel disposed on a first row and a first column; a second pixel which is disposed on the first row and a second column adjacent to the first column along a first direction; a third pixel which is disposed on a second row adjacent to the first row along a second direction and the first column; and a fourth pixel disposed on the second row and the second column.

The power connection lines may include a plurality of first power connection lines which supplies a high potential voltage and is disposed along the second direction on a third column between the first column and the second column; and a plurality of second power connection lines which supplies a low potential voltage and is disposed along the second direction on a fourth column adjacent to the second column along the first direction.

Each of the first power connection lines may be electrically connected to at least one of the connection lines and each of the second power connection lines is electrically connected to at least one of the connection lines.

The pattern layer may further include a plurality of second plate patterns each disposed on the third column; a plurality of third plate patterns each disposed on the fourth column; and a plurality of second line patterns each disposed on the third column and the fourth column.

Each of the second plate patterns and each of the third plate patterns may be disposed in an area between the first plate patterns.

A second line pattern disposed on the third column, among the second line patterns, may be disposed between adjacent second plate patterns to connect the adjacent second plate patterns and a second line pattern disposed on the fourth column, among the second line patterns, may be disposed between adjacent third plate patterns to connect the adjacent third plate patterns.

Each of the first power connection lines may be disposed in a second line pattern disposed on the third column, among the second line patterns, and at least a part of the second plate patterns and each of the second power connection lines is disposed in a second line pattern disposed on the fourth column, among the second line patterns, and at least a part of the third plate patterns.

The first power connection lines may be electrically connected to each other through contact holes formed in one side and the other side of the second plate pattern and the second power connection lines may be electrically connected to each other through contact holes formed in one side and the other side of the third plate pattern.

The contact holes formed in one side and the other side of the second plate patterns may be electrically connected to a first bridge disposed on the second plate pattern and the contact holes formed in one side and the other side of the third plate patterns may be electrically connected to a second bridge disposed on the third plate pattern.

The first bridge may be disposed on a layer different from that of connection lines which extend along the first direction to be disposed on the second plate pattern, among the connection lines, and the second bridge may be disposed on a layer different from that of the connection lines which extend along the first direction to be disposed on the third plate pattern, among the connection lines.

The first to third plate patterns and the first and second line patterns may include the same material.

The first to third plate patterns and the first and second line patterns may be integrally formed.

Among the pixels, pixels disposed on the first row and pixels disposed on the second row may be disposed to be opposite to each other with respect to a reference line parallel to the first direction.

The power connection lines may further include a plurality of third power connection lines which supplies the high potential voltage and is disposed along the first direction on a third row between the first row and the second row; and a plurality of fourth power connection lines which supplies the low potential voltage and is disposed along the first direction on a fourth row adjacent to the second row along the second direction.

The first power connection lines and the third power connection lines may be electrically connected to each other in a first area in which the third column and the third row intersect and the second power connection lines and the fourth power connection lines may be electrically connected to each other in a second area in which the fourth column and the fourth row intersect.

The pattern layer may further include a plurality of fourth plate patterns each disposed on the third row; a plurality of fifth plate patterns each disposed on the fourth row; and a plurality of third line patterns each disposed on the third row and the fourth row.

Each of the third power connection lines may be disposed in a third line pattern disposed on the third row, among the third line patterns, and at least a part of the fourth plate patterns and each of the fourth power connection lines may be disposed in a third line pattern disposed on the fourth column, among the third line patterns, and at least a part of the fifth plate patterns.

The first to fifth plate patterns and the first to third line patterns may include the same material.

The connection lines and the power connection lines may include the same material.

Although the example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a lower substrate which includes an active area and a non-active area and is stretchable;
a pattern layer which is disposed on the active area of the lower substrate and includes a plurality of first plate patterns and a plurality of first line patterns;
a plurality of pixels which is disposed on each of the plurality of first plate patterns;
a plurality of connection lines respectively disposed on each of the plurality of first line patterns and configured to connect the pixels; and
a plurality of power connection lines configured to supply a power voltage to the pixels,
wherein the power connection lines are disposed between the pixels on the active area.

2. The display device according to claim 1, wherein the pixels includes:
a first pixel disposed on a first row and a first column;
a second pixel disposed on the first row and a second column adjacent to the first column along a first direction;
a third pixel disposed on a second row adjacent to the first row along a second direction and the first column; and
a fourth pixel disposed on the second row and the second column.

3. The display device according to claim 2, wherein the power connection lines include:
a plurality of first power connection lines configured to supply a high potential voltage and disposed along the second direction on a third column between the first column and the second column; and
a plurality of second power connection lines configured to supply a low potential voltage and disposed along the second direction on a fourth column adjacent to the second column along the first direction.

4. The display device according to claim 3, wherein each of the first power connection lines is electrically connected to at least one of the connection lines and each of the second power connection lines is electrically connected to at least one of the connection lines.

5. The display device according to claim 3, wherein the pattern layer further includes:
a plurality of second plate patterns each disposed on the third column;
a plurality of third plate patterns each disposed on the fourth column; and
a plurality of second line patterns each disposed on the third column or the fourth column.

6. The display device according to claim 5, wherein each of the second plate patterns and each of the third plate patterns are disposed in an area between the first plate patterns.

7. The display device according to claim 5, wherein:
a second line pattern disposed on the third column, among the second line patterns, is disposed between adjacent second plate patterns and connects the adjacent second plate patterns, and
a second line pattern disposed on the fourth column, among the second line patterns, is disposed between adjacent third plate patterns and connects the adjacent third plate patterns.

8. The display device according to claim 5, wherein:
each of the first power connection lines is disposed in a second line pattern disposed on the third column, among the second line patterns, and at least a part of the second plate patterns, and
each of the second power connection lines is disposed in a second line pattern disposed on the fourth column, among the second line patterns, and at least a part of the third plate patterns.

9. The display device according to claim 8, wherein the first power connection lines are electrically connected to each other through contact holes formed in a first side and a second side of the second plate pattern and the second power connection lines are electrically connected to each other through contact holes formed in a first side and a second side of the third plate pattern.

10. The display device according to claim 9, wherein the contact holes formed in the first side and the second side of the second plate patterns are electrically connected to a first bridge disposed on the second plate pattern, and the contact holes formed in the first side and the second side of the third plate patterns are electrically connected to a second bridge disposed on the third plate pattern.

11. The display device according to claim 10, wherein:
the first bridge is disposed on a layer different from that of connection lines which extend along the first direction and disposed on the second plate pattern, among the connection lines, and
the second bridge is disposed on a layer different from that of the connection lines which extend along the first direction and disposed on the third plate pattern, among the connection lines.

12. The display device according to claim 5, wherein the first, second and third plate patterns and the first and second line patterns include a same material.

13. The display device according to claim 12, wherein the first, second and third plate patterns and the first and second line patterns are integrally formed.

14. The display device according to claim 2, wherein among the pixels, first pixels disposed on the first row and second pixels disposed on the second row are opposite to each other with respect to a reference line parallel to the first direction.

15. The display device according to claim 5, wherein the power connection lines further include:
a plurality of third power connection lines which supplies the high potential voltage and is disposed along the first direction on a third row between the first row and the second row; and
a plurality of fourth power connection lines which supplies the low potential voltage and is disposed along the first direction on a fourth row adjacent to the second row along the second direction.

16. The display device according to claim 15, wherein:
the first power connection lines and the third power connection lines are electrically connected to each other in a first area in which the third column and the third row intersect and the second power connection lines, and
the fourth power connection lines are electrically connected to each other in a second area in which the fourth column and the fourth row intersect.

17. The display device according to claim 15, wherein the pattern layer further includes:
a plurality of fourth plate patterns each disposed on the third row;
a plurality of fifth plate patterns each disposed on the fourth row; and
a plurality of third line patterns each disposed on the third row and the fourth row.

18. The display device according to claim 17, wherein:
each of the third power connection lines is disposed in a third line pattern disposed on the third row, among the third line patterns, and at least a part of the fourth plate patterns, and
each of the fourth power connection lines is disposed in a third line pattern disposed on the fourth column, among the third line patterns, and at least a part of the fifth plate patterns.

19. The display device according to claim 17, wherein the first, second, third, fourth, and fifth plate patterns and the first, second, and third line patterns include a same material.

20. The display device according to claim 1, wherein the connection lines and the power connection lines include the same material.
